(19) United States
(12) Patent Application Publication
(10) Pub. No.: US 2012/0234381 A1
(43) Pub. Date: Sep. 20, 2012

(54) DYE-SENSITIZED SOLAR CELL

(75) Inventors: SOICHIRO ARIMURA, KYOTO (JP); HIROKI TSUJIMURA, KYOTO (JP); SHUNSUKE FURUSE, KYOTO (JP)

(73) Assignee: ROHM CO., LTD., Kyoto (JP)

(21) Appl. No.: 13/421,844

(22) Filed: Mar. 15, 2012

(30) Foreign Application Priority Data
Mar. 17, 2011 (JP) 2011-059349
Oct. 25, 2011 (JP) 2011-233908

(51) Int. Cl. H01L 51/42; H01G 9/155; H01G 9/035; H01L 31/0352

(52) U.S. Cl. 136/255; 136/263; 361/502; 361/505

(57) ABSTRACT

A dye-sensitized solar cell (DSC) is provided, which has an elevated voltage and thus an improved performance achieved with an electrolyte formed by mixing multiple redox electrolytes of an electrolyte solution. The DSC includes: a first substrate 20; a first electrode 10, disposed on the first substrate 20; a porous semiconductor layer 12, disposed on the first electrode 10, and containing semiconductor particles 2 and dye molecules 4; an electrolyte solution 14, formed by dissolving a redox electrolyte in a solvent, in contact with the porous semiconductor layer 12; a second electrode 18, in contact with the electrolyte solution 14; a second substrate 22, disposed on the second electrode 18; and a sealant 16, disposed between the first substrate 20 and the second substrate 22, for sealing the electrolyte solution 14. The redox electrolyte includes an electrolyte formed by mixing multiple redox electrolytes.

### BACKGROUND OF THE INVENTION

1. Field of the Invention

The present invention relates to a dye-sensitized solar cell (DSC), and in particular, to a DSC that has an elevated voltage and thus an improved dye-sensitized performance achieved with an electrolyte, formed by mixing multiple redox electrolytes of an electrolyte solution.

2. Description of the Related Art

In recent years, DSC that is an inexpensive and high-performance solar cell attracts great attention. The DSC is developed by Graetzel from Ecole Polytechnique Fédérale de Lausanne, and has the advantages of high photoelectric conversion efficiency and low manufacturing cost due to the use of titanium oxide carrying a sensitizing dye on a surface, thus being anticipated as the next generation of solar cell.

The DSC includes: a working electrode, having a porous titanium oxide layer carrying a sensitizing dye on a surface; a counter electrode, disposed facing the titanium oxide layer of the working electrode; and an electrolyte solution, filled between the working electrode and the counter electrode (see, for example, Patent Document 1).

A working electrode of a DSC, a DSC including the same, and a method for manufacturing a working electrode of a DSC have been disclosed, where a transparent electrode of a porous oxide semiconductor layer carrying a sensitizing dye on a surface is configured to have depression-protrusion structures on the surface to increase the surface area, thereby capturing more light and improving the photoelectric conversion efficiency (see, for example, Patent Document 2).

Moreover, in the configuration of a DSC disclosed in the prior art, an anti-reflection coating is formed on a surface at a side of a transparent substrate without a transparent electrode disposed, thereby improving the photoelectric conversion efficiency (see, for example, Patent Document 3).

### PRIOR ART DOCUMENT

Patent Document 1: Japanese Patent Publication No. 1999-135817

Patent Document 2: Japanese Patent Publication No. 2007-115514

Patent Document 3: Japanese Patent Publication No. 2003-123859

### SUMMARY OF THE INVENTION

The objective of the present invention is to provide a dye-sensitized solar cell (DSC) that has an elevated voltage and thus an improved performance achieved with an electrolyte formed by mixing multiple redox electrolytes of an electrolyte solution.

According to an aspect of the present invention, a DSC is provided. The DSC includes: a first substrate; a first electrode, disposed on the first substrate; a porous semiconductor layer, disposed on the first electrode; and a charge transport layer, in contact with the porous semiconductor layer, and having a solvent and multiple redox electrolytes.

According to another aspect of the present invention, a DSC is provided. The DSC includes: a first substrate; a first electrode, disposed on the first substrate; a porous semiconductor layer, disposed on the first electrode, and containing semiconductor particles and dye molecules; an electrolyte solution, formed by dissolving a redox electrolyte in a solvent, in contact with the porous semiconductor layer; a second electrode, in contact with the electrolyte solution; a second substrate, disposed on the second electrode; and a sealant, disposed between the first substrate and the second substrate, for sealing the electrolyte solution. The redox electrolyte includes an electrolyte formed by mixing multiple redox electrolytes.

According to the present invention, a DSC is provided which has an elevated voltage and thus an improved performance is achieved with an electrolyte formed by mixing multiple redox electrolytes of an electrolyte solution.

### BRIEF DESCRIPTION OF THE DRAWINGS

The invention will be described according to the appended drawings in which:

FIG. 1 is a schematic cross-sectional structural view of a DSC according to a first embodiment;

FIG. 2 is a schematic structural view of semiconductor particles of a porous semiconductor layer in FIG. 1;

FIG. 3 is a diagram illustrating a working principle of the DSC according to the first embodiment;

FIG. 4 is a diagram illustrating a working principle of the DSC according to the first embodiment based on a charge exchange reaction in an electrolyte solution;

FIG. 5 is a potential energy diagram of a porous semiconductor layer (12), dye molecules (32) and an electrolyte solution (14) in the DSC according to the first embodiment.

FIG. 6 is an enlarged view of a part J of the potential energy diagram of the porous semiconductor layer (12), the dye molecules (32) and the electrolyte solution (14) in the DSC according to the first embodiment in FIG. 5;

FIG. 7 is a diagram illustrating a relationship between an open circuit voltage Voc and an addition amount of LiBr [an addition amount of LiI] in the DSC according to the first embodiment;

FIG. 8 is a diagram illustrating a relationship between a short circuit current density Jsc and an addition amount of LiBr [an addition amount of LiI] in the DSC according to the first embodiment;

FIG. 9 is a diagram illustrating a relationship between a current density and a voltage with an addition amount of LiBr [an addition amount of LiI] as a parameter in the DSC according to the first embodiment;

FIG. 10 is a diagram illustrating a relationship between a maximum generated electricity and an addition amount of LiBr [an addition amount of LiI] in the DSC according to the first embodiment;

FIG. 11 is a diagram illustrating a relationship between a short circuit current density Jsc and a TBABr concentration in the DSC according to the first embodiment;

FIG. 12 is a diagram illustrating a relationship between an open circuit voltage Voc and a TBABr concentration in the DSC according to the first embodiment;

FIG. 13 is a schematic cross-sectional structural view of a DSC according to a second embodiment;

FIG. 14 is a schematic configuration diagram of a plane pattern of the DSC according to the second embodiment;

FIG. 15 is a schematic cross-sectional structural view of FIG. 14 along a line I-I;

FIG. 16 is a schematic configuration diagram of a plane pattern of a DSC according to Variant Example of the second embodiment;

FIG. 17 is a schematic cross-sectional structural view of FIG. 16 along a line II-II;

FIG. 18 is a schematic cross-sectional structural view of FIG. 16 along a line III-III;

FIG. 19(a) is a configuration diagram of a plane pattern of a working electrode in a DSC according to Comparative Example, and FIG. 19(b) is a schematic cross-sectional structural view of FIG. 19(a) along a line IV-IV;

FIG. 20(a) is a configuration diagram of a schematic plane pattern (Embossed Structure Example 1) of a working electrode formed through an embossing and transfer technology in the DSC according to the second embodiment, and FIG. 20(b) is an enlarged view of a part P of FIG. 20(a);

FIG. 21(a) is a configuration diagram of a schematic plane pattern (Embossed Structure Example 2) of a working electrode formed through an embossing and transfer technology in the DSC according to the second embodiment, FIG. 21(b) is an enlarged view of a part Q of FIG. 20(a), and FIG. 21(c) is a schematic cross-sectional structural view of FIG. 20(a) along a line V-V;

FIG. 22(a) is a configuration diagram of a schematic plane pattern (Embossed Structure Example 3) of a working electrode formed through an embossing and transfer technology in the DSC according to the second embodiment, and FIG. 22(b) is an enlarged view of a part Q of FIG. 22(b);

FIG. 23(a) is a diagram illustrating a distance between a deepest part and a surface of a porous semiconductor layer in the DSC according to Comparative Example, and FIG. 23(b) is a diagram illustrating a distance between a deepest part and a surface of a processed porous semiconductor layer in the DSC according to the second embodiment;

FIG. 24(a) is a diagram illustrating a dye penetrated region 12p (an impregnation length d) at an impregnation time t of the porous semiconductor layer in the DSC according to Comparative Example, and FIG. 24(b) is a diagram illustrating a impregnation length d′ at an impregnation time t′ that is greater than t of the porous semiconductor layer in the DSC according to Comparative Example;

FIG. 25(a) is a diagram illustrating a dye penetrated region 12p (an impregnation length d) at an impregnation time t of the porous semiconductor layer in the DSC according to the second embodiment, and FIG. 25(b) is a diagram illustrating a porous semiconductor layer 12a at an impregnation time t′ this is greater than t in the DSC according to the second embodiment;

FIG. 26(a) is a diagram illustrating a cross section of a pattern and sizes of structures in the DSC according to the second embodiment, and FIG. 26(b) is a diagram illustrating a necessary impregnation length c/2 accompanying dye adsorption in the DSC according to the second embodiment;

FIG. 27 is a diagram illustrating a relationship between the impregnation time t required for obtaining a necessary impregnation length c/2 and a pitch p with a protrusion occupancy x as a parameter in the DSC according to the second embodiment;

FIG. 28 is a scanning electron microscope (SEM) photograph of a cross section close to the porous semiconductor layer in the DSC according to Comparative Example;

FIG. 29 is a diagram illustrating a relationship between a C signal strength from an energy dispersive x-ray spectroscope (EDX) and a depth with the impregnation time t as a parameter in the DSC according to the second embodiment;

FIG. 30 is a diagram illustrating a relationship between a dye density and the depth with the impregnation time t as a parameter in the DSC according to the second embodiment;

FIG. 31 is a diagram illustrating a relationship between the impregnation time t and the impregnation length d in the DSC according to the second embodiment;

FIG. 32 shows a simulation result of a relationship between the concentration of the dye molecules generated due to diffusion in the porous semiconductor layer and a space X with the impregnation time t as a parameter in the DSC according to the second embodiment;

FIG. 33 shows a simulation result of a relationship between the impregnation time t and the impregnation length d in the DSC according to the second embodiment;

FIG. 34(a) is an SEM photograph of a surface of a die useful for the embossing transfer in the DSC according to the second embodiment, and FIG. 34(b) is an SEM photograph of a cross section of the die in the FIG. 34(a);

FIG. 35(a) is an SEM photograph of a surface of a porous semiconductor layer after embossing processing by using the die in FIG. 34 in the DSC according to the second embodiment, and FIG. 35(b) is an enlarged SEM photograph of a cross section of the porous semiconductor layer in FIG. 34(a);

FIG. 36 is a diagram illustrating sizes of parts in the enlarged SEM photograph of the porous semiconductor layer in FIG. 35(b);

FIG. 37(a) is a diagram illustrating a configuration of a plane pattern in FIG. 35(a), FIG. 37(b) is a schematic cross-sectional structural view of FIG. 37(a) along a line VI-VI, and FIG. 37(c) is a schematic cross-sectional structural view of FIG. 37(a) along a line VII-VII, whereby FIG. 37(a), FIG. 37(b), and FIG. 37(c) are used to illustrate FIG. 36;

FIG. 38(a) is a schematic top view of a processed porous semiconductor layer of the DSC according to the second embodiment (Structural Example 1), FIG. 38(b) is a schematic top view of a processed porous semiconductor layer of the DSC according to the second embodiment (Structural Example 2), and FIG. 38(c) is a schematic top view of a processed porous semiconductor layer of the DSC according to the second embodiment (Structural Example 3);

FIG. 39(a) shows Structural Example 1 of a schematic plane pattern of a processed porous semiconductor layer in the DSC according to the second embodiment, and FIG. 39(b) shows Structural Example 2 of a schematic plane pattern of a processed porous semiconductor layer in the DSC according to the second embodiment;

FIG. 40 is a schematic cross-sectional structural view of a porous semiconductor layer with grooves having a side wall of a vertical shape in the DSC according to the second embodiment;

FIG. 41 is a schematic cross-sectional structural view of a porous semiconductor layer with grooves having a side wall of a taper shape in the DSC according to the second embodiment;

FIG. 42 is a schematic cross-sectional structural view of a porous semiconductor layer with wedge-like grooves having a side wall of a taper shape in the DSC according to the second embodiment;

FIG. 43 is a schematic cross-sectional structural view of a porous semiconductor layer with grooves having a side wall of an inverted taper shape in the DSC according to the second embodiment;

FIG. 44 is a schematic cross-sectional structural view of a porous semiconductor layer with grooves reaching a transparent electrode 10 in the DSC according to the second embodiment;

FIG. 45 is a schematic cross-sectional structural view of a porous semiconductor layer with grooves having a side wall of a multi-segment shape in the DSC according to the second embodiment;

FIG. 46 is a schematic cross-sectional structural view of a porous semiconductor layer with grooves having a side wall of a curved surface shape in the DSC according to the second embodiment;

FIG. 47 is a schematic cross-sectional structural view of a step of a method for manufacturing the DSC according to the second embodiment (part 1);

FIG. 48 is a schematic cross-sectional structural view of a step of a method for manufacturing the DSC according to the second embodiment (part 2);

FIG. 49 is a schematic cross-sectional structural view of a step of a method for manufacturing the DSC according to the second embodiment (part 3);

FIG. 50 is a schematic cross-sectional structural view of a step of a method for manufacturing the DSC according to the second embodiment (part 4);

FIG. 51 is a schematic cross-sectional structural view of a step of a method for manufacturing the DSC according to the second embodiment (part 5);

FIG. 52 is a schematic cross-sectional structural view of a step of a method for manufacturing the DSC according to the second embodiment (part 6);

FIG. 53 is a schematic cross-sectional structural view of a step of a method for manufacturing the DSC according to the second embodiment (part 7);

FIG. 54(a) is a schematic cross-sectional structural view of a step of another method for manufacturing the DSC according to the second embodiment (part 1), FIG. 54(b) is a schematic cross-sectional structural view of a step of the another method for manufacturing the DSC according to the second embodiment (part 2), FIG. 54(c) is a schematic cross-sectional structural view of a step of the another method for manufacturing the DSC according to the second embodiment (part 3), and FIG. 54 (d) is a schematic cross-sectional structural view of a step of the another method for manufacturing the DSC according to the second embodiment (part 4);

FIG. 55(a) is a schematic cross-sectional structural view of a step of another method for manufacturing the DSC according to the second embodiment (part 1), and FIG. 55(b) is a schematic cross-sectional structural view of a step of the another method for manufacturing the DSC according to the second embodiment (part 2);

FIG. 56(a) is a schematic cross-sectional structural view of a step of another method for manufacturing the DSC according to the second embodiment (part 1), and FIG. 56(b) is a schematic cross-sectional structural view of a step of the another method for manufacturing the DSC according to the second embodiment (part 2);

FIG. 57 is a schematic cross-sectional structural view of internal electrodes of an exemplary electric double-layer capacitor (EDLC) according to a third embodiment;

FIG. 58 is a schematic cross-sectional structural view of internal electrodes of an exemplary lithium ion capacitor according to a fourth embodiment; and

FIG. 59 is a schematic cross-sectional structural view of internal electrodes of an exemplary lithium ion capacitor according to a fifth embodiment.

### DETAILED DESCRIPTION OF THE INVENTION

Hereinafter, embodiments are described with reference to the accompanying drawings. In the accompanied drawings, the same or similar parts are labeled with the same or similar symbols. However, it should be noted that, the accompanying drawings are schematic views, so the relationships between the thickness, the plane size and the ratio of the thickness of the layers differ from those of the real objects. Therefore, the specific thinness and size should be determined according to the following description. Moreover, in the accompanying drawings, the different sizes, relationships and ratios are also included.

Moreover, the following embodiments are intended to exemplify the devices and methods that embody the technical ideas of the present invention, and are not intended to specify the material, the shape, the structure and the configuration of the parts to be limited those described below. Various changes may be made to the embodiments of the present invention while remaining within the scope of the claims.

For a semiconductor light emitting device according to the following embodiments, the so-called “transparent” is defined as having a transmission rate of about 50% or more. For the semiconductor light emitting device according to the embodiments, the so-called “transparent” may have the meaning of being colorless and transparent in terms of the visible light. The visible light is light having a wavelength of about 360 nm-830 nm and an energy of about 3.45 eV-1.49 eV, and the semiconductor light emitting device is transparent provided that the transmission rate of light in the range is 50% or more.

### First Embodiment

### (DSC)

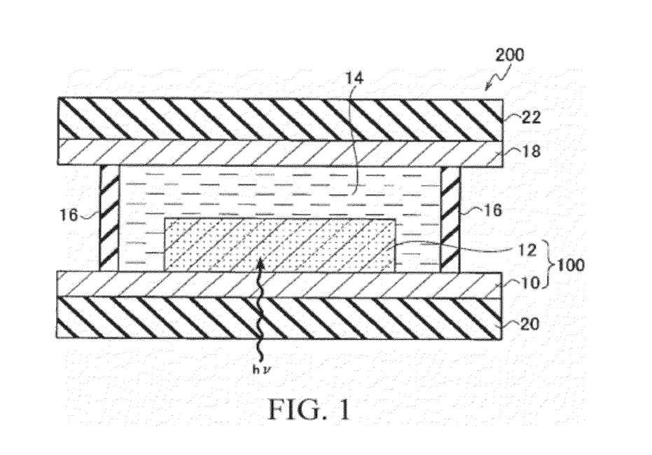

A schematic cross-sectional structural view of a DSC 200 according to the first embodiment is shown in FIG. 1.

As shown in FIG. 1, a working electrode 100 useful in the DSC 200 according to the first embodiment includes: a transparent electrode 10, disposed on a glass substrate 20; and a porous semiconductor layer 12, disposed on the transparent electrode 10.

As shown in FIG. 1, the DSC 200 according to the first embodiment includes: the glass substrate 20; the transparent electrode 10, disposed on the glass substrate 20; the porous semiconductor layer 12, disposed on the transparent electrode 10; and a charge transport layer 14, in contact with the porous semiconductor layer 12, and containing a solvent and an electrolyte formed by mixing multiple redox electrolytes. Herein, the charge transport layer 14 contains an electrolyte formed by mixing multiple redox electrolytes, so the open circuit voltage is high and the electricity generation is increased, when compared with the situation where a redox electrolyte alone is used.

Particularly, as shown in FIG. 1, the DSC according to the first embodiment includes: the first substrate 20; the first electrode 10, disposed on the first substrate 20; the porous semiconductor layer 12, disposed on the first electrode 10 and containing semiconductor particles 2 and dye molecules 4; an electrolyte solution 14, formed by dissolving a redox electrolyte in a solvent, in contact with the porous semiconductor layer 12; a second (counter) electrode 18, in contact with the electrolyte solution 14; a second substrate 22, disposed on the second electrode 18; and a sealant 16, disposed between the first substrate 20 and the second substrate 22, for sealing the electrolyte solution 14. Herein, the redox electrolyte includes an electrolyte formed by mixing multiple redox electrolytes.

The first substrate 20 and the second substrate 22 may, for example, be formed by a glass substrate. Moreover, a flexible plastic substrate may also be used. In this case, a TiO₂ slurry that is sintered at a temperature of 200° C. or lower may be used. In order to allow the light incident to be transmitted from a side of the first substrate 20, the first substrate 20 is desirably transparent in term of the incident light. Furthermore, an anti-reflection coating may also be coated on the side of the first substrate 20 from which the light is incident.

The first electrode 10 may, for example, be formed by a transparent electrode of FTO, ZnO, ITO or SnO₂. The first substrate 20 may be subjected to electrode processing to form a substrate with FTO, a substrate with a gate made of a metal or a composite substrate thereof.

As the porous semiconductor layer 12 of the DSC 200 according to the first embodiment is needed to maintain the balance between the Fermi energy and the redox energy of a redox electrolyte, an oxide semiconductor may be used.

The porous semiconductor layer 12 may also be formed with a material of TiO₂, ZnO, WO₃, InO₃, ZrO₂, Ta₂O₃, Nb₂O₃ or SnO₂. In view of efficiency, cheap TiO₂ (anatase type or rutile type) is mainly used.

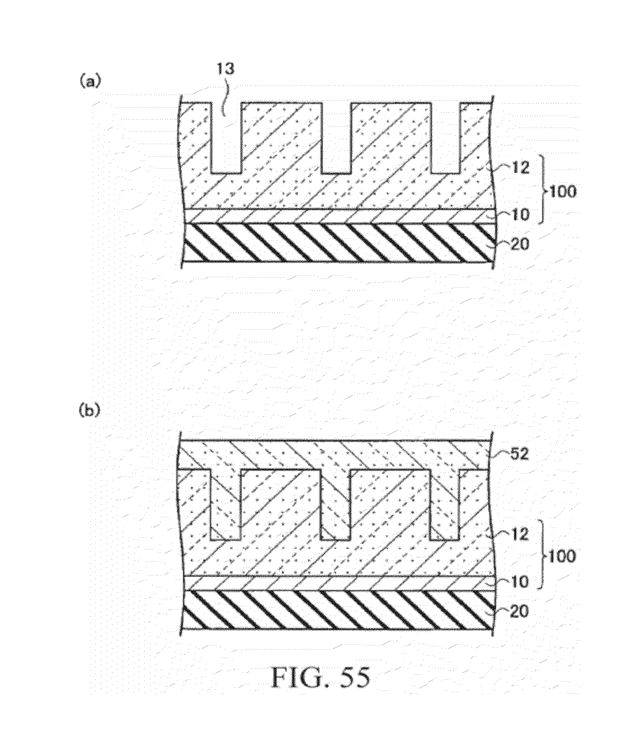

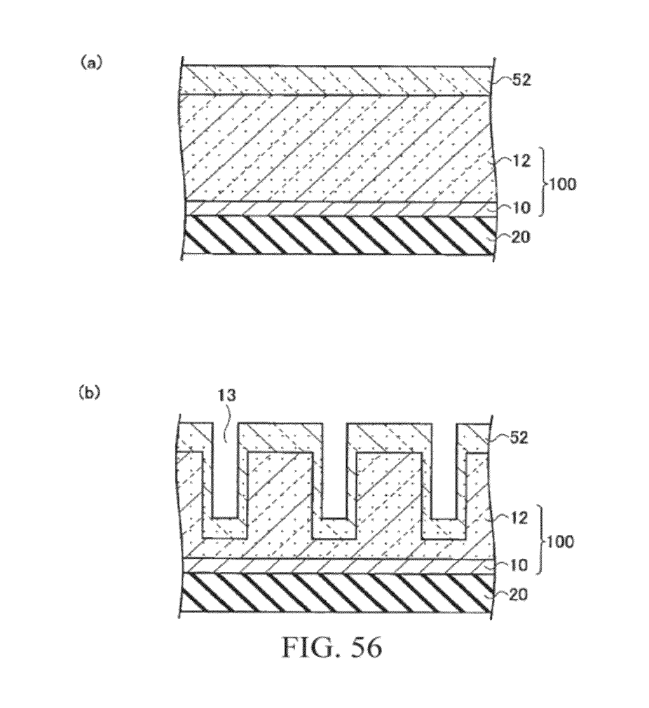

Herein, on the porous semiconductor layer 12, a light-scattering layer (52: FIG. 55(b) and FIG. 56(b)) may also be included. The light-scattering layer may, for example, be formed by TiO₂ particles or ZrO₂ particles with a particle size of about 200 nm.

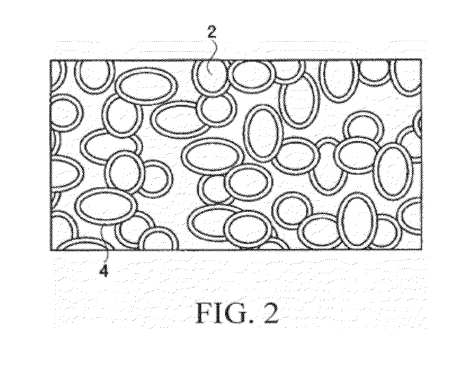

A schematic structural view of the semiconductor particles 2 of the porous semiconductor layer 12 in FIG. 1 is shown in FIG. 2. As shown in FIG. 2, the semiconductor particles 2 of, for example, TiO₂ contained in the porous semiconductor layer 12 are joined to each other to form a complex network structure. The dye molecules 4 are adsorbed by the surface of the semiconductor particles 2. In the porous semiconductor layer 12, numerous pores with a size of 100 nm or lower exist.

### (Working Principle)

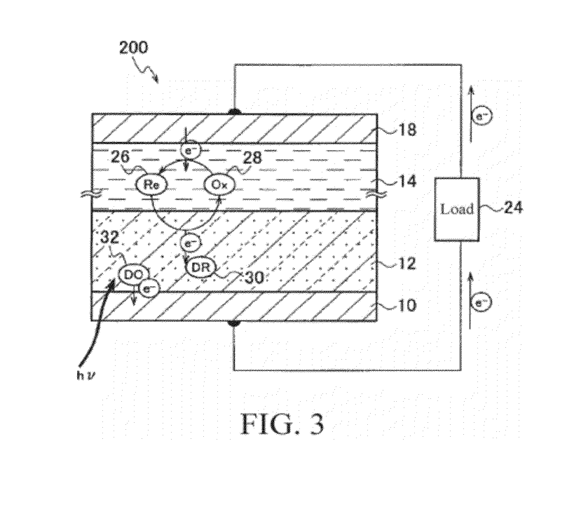

The working principle of the DSC 200 according to the first embodiment is shown in FIG. 3.

An electromotive force is generated through the following continuous reactions of (a)-(d), and a current is conducted in a load 24.

(a) Dye molecules 32 absorb photons (hν) and release electrons (e⁻), becoming an oxidized species of DO.

(b) A redox electrolyte 26 as a reduced species represented by Re diffuses in the porous semiconductor layer 12, and approaches the dye molecules 32 of the oxidized species represented by DO.

(c) The electrons (5) are delivered from the redox electrolyte 26 to the dye molecules 32. The redox electrolyte 26 becomes a redox electrolyte 28 that is an oxidized species represented by Ox, and the dye molecules 32 become reduced dye molecules 30 that is represented by DR.

(d) The redox electrolyte 28 diffuses towards the counter electrode 18, and obtains electrons delivered from the counter electrode 18, and becomes the redox electrolyte 26 that is a reduced species represented by Re.

The redox electrolyte 26 needs to approach the dye molecules 32 while diffusing in a complex space in the porous semiconductor layer 12.

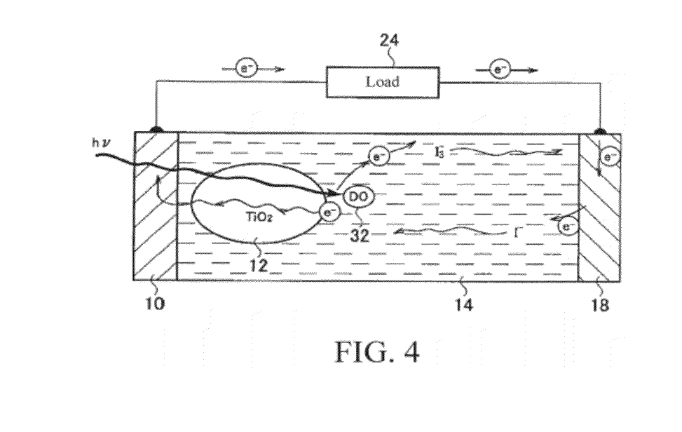

Moreover, the working principle of the DSC 200, according to the first embodiment based on the charge exchange reaction in the electrolyte solution 14, is shown in FIG. 4.

First, if the light is incident is from outside, the photons (hν) react with the dye molecules 32, and dye molecules 32 transit from a baseline state to an excited state. At this time, the generated excited electrons (e⁻) are released into a conduction band of the porous semiconductor layer 12 containing TiO₂. In the porous semiconductor layer 12, the conducted electrons (e⁻) moves from the transparent electrode 10 to the counter electrode 18, during which the load 24 of an external circuit is conducted. Charge exchange occurs between the electrons (e⁻) released into the electrolyte solution 14 from the counter electrode 18 and an iodine-based redox electrolyte (I⁻/I₃⁻) in the electrolyte solution 14. The iodine-based redox electrolyte (I⁻/I₃⁻) diffuses in the electrolyte solution 14, and reacts once again with the dye molecules 32. Herein, the charge exchange reaction occurs on the surface of the dye molecules, in the form of 3I⁻→I₃⁻+2e⁻, and occurs in the counter electrode 18 in the form of I₃⁻+2e⁻→3I⁻.

For example, in the electrolyte solution 14, acetonitrile is used as a solvent and iodine electrolyte exists as an iodine-based redox electrolyte I₃⁻ in the electrolyte solution 14. Moreover of that example, an iodide electrolyte (e.g. lithium iodide or potassium iodide) exists as an iodine-based redox electrolyte I⁻ in the electrolyte solution 14. Moreover, an additive (for example, t-butyl pyridine, TBP) may be used in the electrolyte solution 14 as a reverse electron transferring inhibition solution.

The solute and the additive are dissolved in the solvent (acetonitrile) to form the electrolyte solution 14. Furthermore, the materials may be used in a wet DSC. The materials used are also different situation where a normal-temperature molten salt (an ionic liquid) or a solid electrolyte is used.

In the DSC 200 according to the first embodiment, the solvent is a liquid for dissolving the electrolyte and the additive, which preferably has a high boiling point, a high chemical stability, a high dielectric constant (so that the electrolyte can be more easily dissolved) and a low viscosity. For example, the solvent may be selected from acetonitrile, propylene carbonate, y-butyrolactone, methoxyacetonitrile, propionitrile, ethylene carbonate, and propylene carbonate.

The electrolyte solution 14 useful in the DSC 200 according to the first embodiment contains, for example, an electrolyte formed by mixing multiple redox electrolytes including an iodine-based redox electrolyte and a bromine-based redox electrolyte. If the composition ratio of the used iodine-based redox electrolyte and bromine-based redox electrolyte is X, the electrolyte may be expressed as LiI_{X}Br_{i-X}. Herein, the composition ratio X is controlled, so as to control the concentration ratio of the redox electrolytes. Through the controlling of thee concentration ratios of the redox electrolytes, the open circuit voltage Voc, the short circuit current density Jsc and the maximum generated electricity are controlled in the following manner. As for the redox electrolyte, in addition to the iodine-based redox electrolyte and the bromine-based redox electrolyte, a chlorine-based redox electrolyte and ferrocene may also be used. A mixed redox electrolyte system includes a mixture system selected from the group consisting of an iodine-based redox electrolyte, a bromine-based redox electrolyte, a chlorine-based redox electrolyte and ferrocene.

Herein, the electrolyte solution 14 may contain primary to quaternary ammonium ions, bromine ions and iodide ions.

In this case, the concentration of the bromine ion in the electrolyte solution 14 may be lower than the concentration of the iodide ion.

Moreover, the concentration of the bromine ion in the electrolyte solution 14 may be one half or less of the concentration of iodide ion.

Moreover, the primary to quaternary ammonium ions may include any one of tetrabutyl ammonium, tetramethyl ammonium, trimethylmethanaminium, hexadecyl-trimethyl-ammonium, trimethylanilinium or trimethylbenzeneaminium.

Furthermore, the so-called alkyl refers to a linear hydrocarbyl (excluding an aryl such as phenyl); the so-called anilinium refers to a compound of aniline (an ammonium salt); the so-called ammonium refers to an ionized species formed by adding H⁺ to an amine; and the so-called amine refers to a species formed by replacing H in ammonia with a hydrocarbyl.

Moreover, the so-called primary to quaternary ammoniums refer to species formed by replacing H in ammonium (NH₄) with a hydrocarbyl, and the order number of 1 to 4 is determined by the number of H replaced.

The additive is added to the electrolyte solution and is adsorbed by the surface of the porous semiconductor layer 12 containing, for example, TiO₂, thereby improving the electricity generation characteristic of the DSC. Examples of the additive include, for example, pyridines, imidazoles and isothiocyanates.

Furthermore, the dye may be a red dye (N719) or a black dye (N749).

The counter electrode 18 may, for example, be formed by Pt, C or a conductor polymer. The conductor polymer may also be formed by, for example, poly(3,4-ethylenedioxythiophene:poly(styrenesulfonate) (PEDOT:PSS).

The porous semiconductor layer 12 may, for example, be formed by using screen printing technology, spin coating technology, dipping or spraying technology.

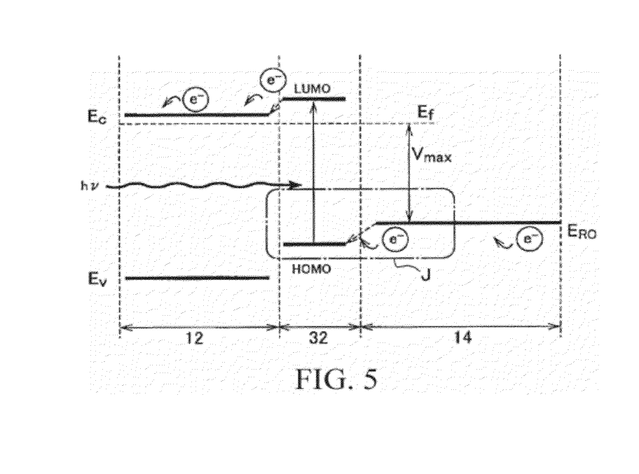

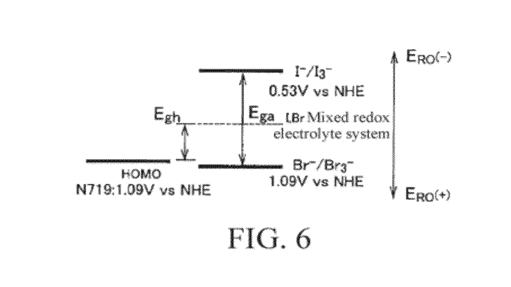

In the DSC 200 according to the first embodiment, a potential energy diagram of the porous semiconductor layer (12), the dye molecules (32), and the electrolyte solution (14) is shown in FIG. 5. Moreover, a potential energy diagram of the dye molecules (32), and the electrolyte solution (14), that is, an enlarged view of a part J in FIG. 5, is shown in FIG. 6.

If the light is incident from outside, the photons (hν) react with the dye molecules 32, and the dye molecules 32 transit from a dormant-state highest occupied molecular orbital (HOMO) to an excited-state lowest unoccupied molecular orbital (LUMO). At this time, the generated excited electrons (e⁻) are released into a conduction band of the porous semiconductor layer 12 containing TiO₂. In the porous semiconductor layer 12, the conducted electrons (e⁻) move from the transparent electrode 10 to the counter electrode 18, during which the load 24 of the external circuit is conducted. Charge exchange occurs between the electrons (e⁻) released into the electrolyte solution 14 from the counter electrode 18 and a mixture system containing an iodine-based redox electrolyte in the electrolyte solution 14. The mixture system containing the iodine-based redox electrolyte diffuses in the electrolyte solution 14, and reacts yet again with the dye molecules 32.

The potential difference between the redox energy level E_{RO} of the electrolyte solution 14 and the Fermi energy level E_{f} of the porous semiconductor layer 12 is a maximum electromotive force V_{MAX}. The value of the maximum electromotive force V_{MAX} varies with the redox electrolyte in the electrolyte solution 14. In a single redox electrolyte system (only containing iodine-based redox electrolyte), the maximum electromotive force V_{MAX} is, for example, 0.9 V (I, N719). When the electrolyte 14 contains an iodine-bromine mixed redox electrolyte system, as shown in FIG. 6, it is considered to adjust the mixing ratio to adjust the redox potential of the mixed redox electrolyte system to be any value between the redox potential of the iodine-based redox electrolyte and the redox potential of the bromine-based redox electrolyte.

As shown in FIG. 6, when the ratio of the bromine-based redox electrolyte mixed in the electrolyte solution 14 is zero, the redox energy level E_{RO} is 0.53 V (I/I₃⁻), and in contrast, when the mixed ratio of the iodine-based redox electrolyte is zero, the redox energy level E_{RO} is 1.09 V (Br/Br₃⁻). The value of a band gap Ega therebetween is 1.09−0.53=0.56 V.

In case that a value of the potential difference Egh between the HOMO level and the redox energy level E_{RO} is large, the loss of voltage occurs when the maximum electromotive force V_{MAX} is obtained. When the value of the potential difference Egh between the HOMO level and the redox energy level E_{RO} is low, the movement of the electrons (e⁻) from the electrolyte solution 14 to the dye molecules 32 is hindered.

Therefore, in order to efficiently conduct the electrons (e⁻) from the electrolyte solution 14 to the dye molecules 32 side and to inhibit the voltage loss when the maximum electromotive force V_{MAX} is obtained, it is desirable that the level of the redox energy level E_{RO} is higher than the HOMO level of the dye molecules 32, and the potential difference Egh is as low as possible.

As described below, comparing an electrolyte solution containing an iodine-bromine mixed redox electrolyte system obtained by mixing an iodine-based redox electrolyte and a bromine-based redox electrolyte to the situation where the iodine-based redox electrolyte alone is used, the value of the open circuit voltage is increased with the addition of the bromine-based redox electrolyte. The reason is considered to be that, when compared with the iodine-based redox electrolyte, the redox potential of the bromine-based redox electrolyte is comparatively positive, and with the addition of the bromine-based redox electrolyte, the redox potential of the iodine-bromine mixed redox electrolyte system shifts towards the positive side.

### -Open Circuit Voltage Voc-

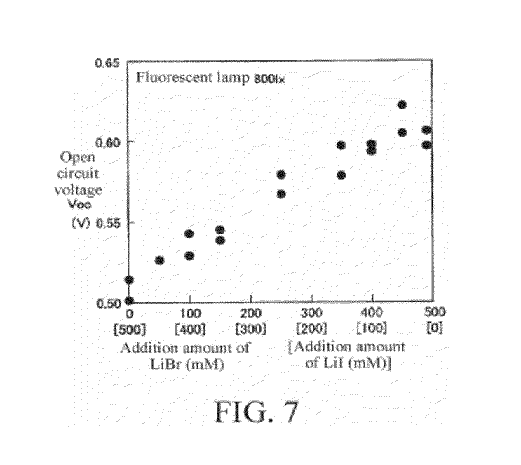

In the DSC according to the first embodiment, a relationship between the open circuit voltage Voc when being irradiated by a fluorescent lamp at 800 lx and the addition amount of LiBr [the addition amount of LiI] is shown in FIG. 7. In FIG. 7, the horizontal axis represents the addition amount of LiBr (mM) and [the addition amount of LiI (mM)]. The unit mM is millimolar, and represents mmol/L. For example, when the addition amount of LiBr (mM) is 0 (mM), the addition amount of LiI (mM) is 500 (mM); when the addition amount of LiBr (mM) is 100 (mM), the addition amount of LiI (mM) is 400 (mM); when the addition amount of LiBr (mM) is 200 (mM), the addition amount of LiI (mM) is 300 (mM); when the addition amount of LiBr (mM) is 300 (mM), the addition amount of LiI (mM) is 200 (mM); when addition amount of LiBr (mM) is 400 (mM), the addition amount of LiI (mM) is 100 (mM); and when the addition amount of LiBr (mM) is 500 (mM), the addition amount of LiI (m) is 0 (mM). It can be known from FIG. 7 that the value of the open circuit voltage Voc is increased by about 0.1 V when the addition amount of LiBr (mM) varies from 0 to 450 (mM) [the addition amount of LiI (m) is 50-50 (mM)].

In the DSC according to the first embodiment, the open circuit voltage Voc is still increased by about 0.1 V, it is indicated that changing the electrolyte solution 14 from a single redox electrolyte system to a mixed redox electrolyte system has a significant effect.

### -Short Circuit Current Density Jsc-

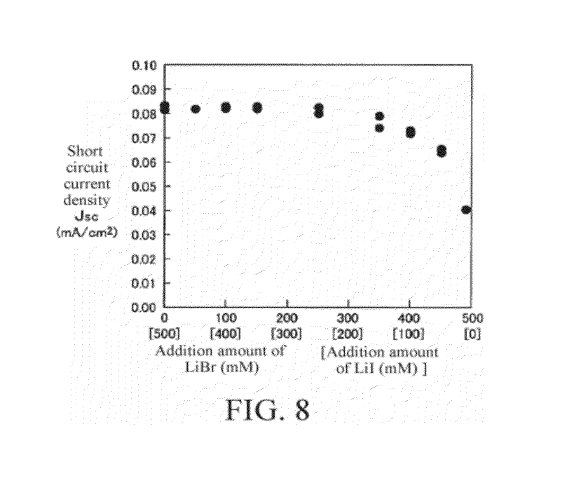

In the DSC according to the first embodiment, the relationship between the short circuit current density Jsc and the addition amount of LiBr [the addition amount of LiI] is shown in FIG. 8. It can be seen from FIG. 8 that in the whole wide range of the addition amount of LiBr (mM) of 0-400 (mM) [the addition amount of LiBr (mM) is 500-100 (mM)], the value of the short circuit current density Jsc is relatively maintained at a high level. The reason is that when the addition amount of LiBr (mM) is 400-500 (mM), the Br concentration is increased, and the band gap Ega in FIG. 6 is increased, but the value of the potential difference Egh between the HOMO level and the redox energy level E_{RO} is lowered, so that the movement of the electrons (e⁻) from the electrolyte solution 14 to the dye molecules 32 is hindered.

### -Maximum Generated Electricity-

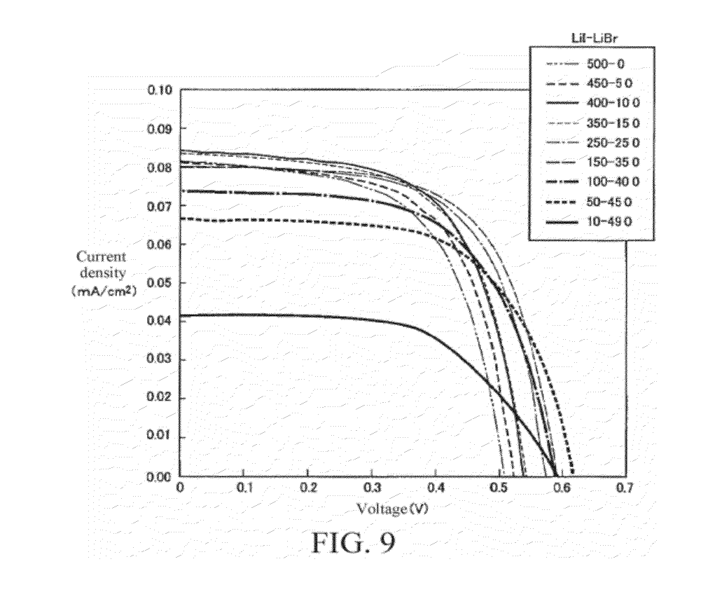

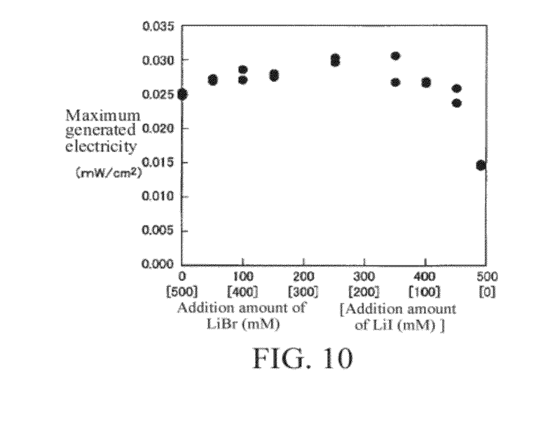

In the DSC according to the first embodiment, the relationship between the current density and the voltage with the addition amount of LiBr [the addition amount of LiI] as a parameter is shown in FIG. 9. Moreover, the relationship of the maximum generated electricity and the addition amount of LiBr [the addition amount of LiI] is shown in FIG. 10. It is clear from FIG. 9 and FIG. 10 that, when the addition amount of LiBr (mM) is 200-400 (mM) [the addition amount of LiBr (mM) is 300-100 (mM)], the maximized electricity generation can be obtained

Herein, the experiments for confirming the short circuit current density Jsc and the maximum generated electricity of the DSC according to the first embodiment are described.

First, a unit for evaluating the DSC according to the first embodiment is fabricated as follows.

(a) A TiO₂ slurry film is formed, through screen printing, on a glass substrate with a transparent conductive film (FTO) that had been subjected to organic cleaning and ultraviolet (UV) ozone cleaning.

(b) TiO₂ printed on the glass substrate is sintered with an electric stove at 400-500° C.

(c) The TiO₂ sintered substrate is immersed over night in a dye solution with a Ru complex (N719, manufactured by Solaronix).

(d) The substrate that had been immersed in the dye solution is cleaned, and attached, through hot melt seal, to a counter electrode substrate with a Pt film.

Next, an electrolyte solution to be injected into the unit for evaluating the DSC is prepared. Particularly, with 4-butyrolactone as a solvent, 500 mM tetrabutyl ammonium iodide, tetrabutyl ammonium bromide, 100 mM lithium iodide, 10 mM iodine, and 1000 mM n-methylbenzimidazol are dissolved, and the electrolyte solution is adjusted by adjusting the concentration of tetrabutyl ammonium bromide (TBABr) to be in a range of 0 to 500 mM.

As an evaluation method, the electrolyte solution that had been adjusted is injected into the fabricated unit for evaluation by means of capillary phenomenon, and the unit for evaluation that is irradiated with a fluorescent lamp at an illuminance of 1000 lx, and the current-voltage property are determined, so as to evaluate the characteristics of the electrolyte solution.

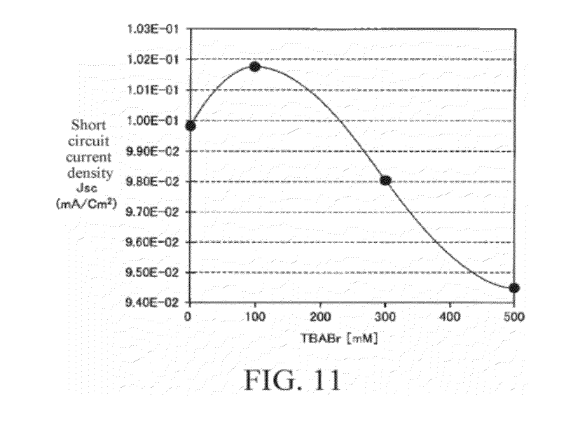

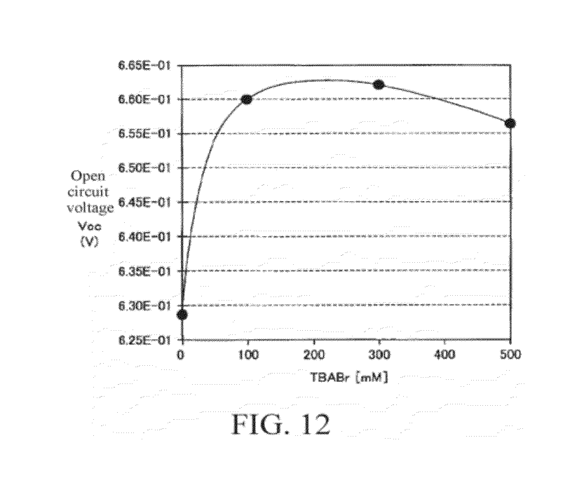

FIG. 11 is a diagram illustrating a relationship between a short circuit current density Jsc and a TBABr concentration in the unit for evaluation (the DSC according to the first embodiment). Moreover, FIG. 12 is a diagram illustrating a relationship between an open circuit voltage Voc and a TBABr concentration in the unit for evaluation (the DSC according to the first embodiment).

As shown in FIG. 11 and FIG. 12, when the concentration of tetrabutyl ammonium bromide (TBABr) is 0 mM, the short circuit current density Jsc is about 1.00E-01 (mA/cm²), and the open circuit voltage Voc is about 6.30E-01 (V). Moreover, when the concentration of tetrabutyl ammonium bromide (TBABr) is 100 mM, the short circuit current density Jsc is about 1.02E-01 (mA/cm²), and the open circuit voltage Voc is about 6.60E-01 (V). Moreover, when the concentration of tetrabutyl ammonium bromide (TBABr) is 300 mM, the short circuit current density Jsc is about 9.80E-02 (mA/cm²), and the open circuit voltage Voc is about 6.62E-01 (V). Moreover, when the concentration of tetrabutyl ammonium bromide

(TBABr) is 500 mM, the short circuit current density Jsc is about 9.45E-02 (mA/cm²), and the open circuit voltage Voc is about 6.57E-01 (V).

In this way, it can be confirmed that by adding tetrabutyl ammonium bromide (TBABr), the open circuit voltage Voc of all adjusted electrolyte solution is increased.

On the other hand, the short circuit current density reaches a peak when the concentration of tetrabutyl ammonium bromide (TBABr) is 100 mM, and when the concentration exceeds 100 mM, the short circuit current density is decreased.

In this way, the reason for the decrease of the short circuit current density when the concentration of tetrabutyl ammonium bromide (TBABr) surpasses the threshold of 100 mM is that when the concentration of bromine (Br) is increased, a virtual redox energy level is decreased, the injection efficiency of the carrier is reduced, and the current value is also reduced accordingly.

It can be confirmed from the above experimental results that in the electrolyte solution of the above composition, the most preferred concentration of tetrabutyl ammonium bromide (TBABr) is 100 mM.

For the dye-sensitized solar cell, the open circuit voltage is determined by a difference between the redox energy level of iodine and the Fermi energy level of TiO₂.

The inventors of the present invention performed the following test. Bromide ions were added to the electrolyte solution to virtually increase the redox potential, so as to increase the open circuit voltage. However, when alkali metal ions are added as counterions of a salt to generate the bromide ions, the voltage is decreased.

On the other hand, the redox energy level can be virtually increased by adding bromine having a redox energy level that is larger than that of iodine, so that the open voltage is increased.

Moreover, by adding a quaternary alkyl ammonium, that can be easily ionized in the electrolyte solution regardless of the solvent, to the bromide ions as the counterions, bromide ions can be effectively generated in the electrolyte solution.

Moreover, by using quaternary alkyl ammonium ions, that has less influence on the working electrode when compared with the alkali metals such as lithium, as the counterions of the bromide ions, the decrease of the open circuit voltage caused by the counterions can be limited.

Moreover, it can be confirmed that by adding a small amount of bromide ions that is about one half or less of that of the iodide ions in the electrolyte solution, the characteristics can be improved.

Moreover, it can be confirmed that the most preferred concentration of tetrabutyl ammonium bromide (TBABr) is 100 mM.

According to the first embodiment, by using an electrolyte solution of a mixed redox electrolyte system in a charge transport layer, a DSC that has a higher open circuit voltage and higher generated electricity is provided, when compared with the situation where a redox electrolyte is used alone.

### Second Embodiment

### (DSC)

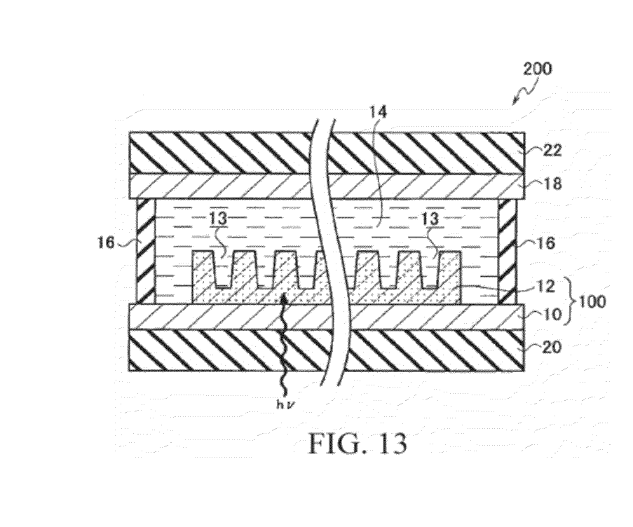

A schematic cross-sectional structural view of a DSC 200 according to the second embodiment is shown in FIG. 13.

As shown in FIG. 13, a working electrode 100 useful in the DSC 200 according to the second embodiment includes: a transparent electrode 10, disposed on a glass substrate 20; and a porous semiconductor layer 12, disposed on the transparent electrode 10, and having grooves 13 on a surface that is not in contact with the transparent electrode 10.

As described below, a side wall with the grooves 13 may have a shape of a vertical shape, a taper shape, a wedge shape, an inverted taper shape, a multi-segment shape, or a curved surface shape.

As shown in FIG. 13, the DSC 200 according to the second embodiment includes: the glass substrate 20; the transparent electrode 10, disposed on the glass substrate 20; the porous semiconductor layer 12, disposed on the transparent electrode 10, and having the grooves 13 on the surface that is not in contact with the transparent electrode 10; and a charge transport layer 14, in contact with the porous semiconductor layer 12, and containing a solvent and an electrolyte formed by mixing multiple redox electrolytes. Herein, the charge transport layer 14 is the same as that of the first embodiment. As the electrolyte formed by mixing the multiple redox electrolytes is contained, the open circuit voltage is high, and the generated electricity is large when compared with the situation where the redox electrolyte is used alone.

Additionally, in the configuration of FIG. 13, the protrusion-depression degree at the interface between the porous semiconductor layer 12 and the transparent electrode 10 is about 20 nm or less.

Particularly, as shown in FIG. 13, the DSC 200 according to the second embodiment includes: the first substrate 20; the first electrode 10, disposed on the first substrate 20; the porous semiconductor layer 12, disposed on the first electrode 10, having the grooves 13 on the surface that is not in contact with the first electrode 10, and containing semiconductor particles 2 and dye molecules 4; the electrolyte solution 14, formed by dissolving a redox electrolyte in a solvent, in contact with the porous semiconductor layer 12; a second electrode 18, in contact with the electrolyte solution 14; a second substrate 22, disposed on the second electrode 18; and a sealant 16, disposed between the first substrate 20 and the second substrate 22, for sealing the electrolyte solution 14. Herein, the redox electrolyte contains an electrolyte formed by mixing multiple redox electrolytes.

The electrolyte solution 14 useful in the DSC 200 according to the second embodiment is the same as that of the first embodiment, so details are not repeated herein again. Moreover, except for the grooves on the surface that is not in contact with the transparent electrode 10, the configuration and the materials of the parts of the porous semiconductor layer 12 are the same as those of the first embodiment, so details are not repeated herein again.

The working principle of the DSC 200 according to the second embodiment is the same as that of FIG. 3, and the working principle based on the charge exchange reaction in the electrolyte solution 14 is the same as that of FIG. 4, so details are not repeated herein again. Additionally, the porous semiconductor layer 12 of the DSC 200 according to the second embodiment has protrusion-depression structures including the grooves 13 on the surface, so the redox electrolyte 26 can easily diffuse in the complex space in the porous semiconductor layer 12 and approach the dye molecules 32.

In the DSC 200 according to the second embodiment, the porous semiconductor layer 12 has the grooves 13, so the adsorption time of the dye onto the porous semiconductor layer 12 is shortened. That is to say, by reducing the distance between the deepest part and the surface of the porous semiconductor layer 12, the time taken for the dye molecules to diffuse to the deepest part can be shortened.

In the DSC 200 according to the second embodiment, the photoelectric conversion efficiency is improved by increasing the density of the reduced redox electrolyte in the porous semiconductor layer 12. That is to say, by reducing the distance between the deepest part and the surface of the porous semiconductor layer 12, the redox electrolyte can diffuse to the deepest part in a shorter period of time, so that more reduced redox electrolyte is supplied to the deepest part, thereby improving the photoelectric conversion efficiency.

In the DSC 200 according to the second embodiment, the photoelectric conversion efficiency is improved by reducing the density of the oxidized redox electrolyte in the porous semiconductor layer 12. That is to say, by reducing the distance between the deepest part and the surface of the porous semiconductor layer 12, the oxidized redox electrolyte generated at the deepest part of the porous semiconductor layer 12 can also diffuse to the outside of the porous semiconductor layer 12 in a much shorter period of time, so the concentration of the oxidized redox electrolyte remained in the porous semiconductor layer 12 can be decreased. Thus, the light absorption effect and the current loss resulting from the oxidized redox electrolyte can be limited, thereby improving the photoelectric conversion efficiency.

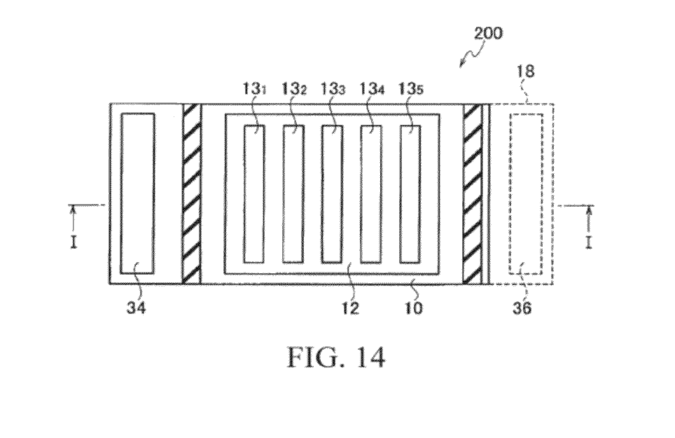

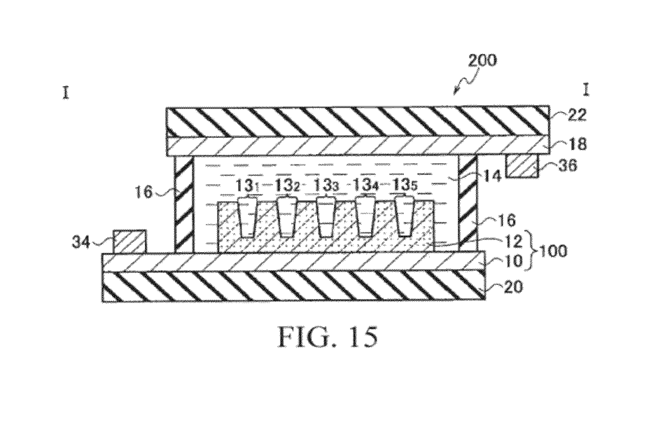

In the DSC according to the second embodiment, an extraction electrode 34 of the working electrode 100 and an extraction electrode 36 of the counter electrode 18 are further included. A configuration of such set out on a schematic plane pattern is shown in FIG. 14, and a schematic cross-sectional structural view along a ling I-I in FIG. 14 is shown in FIG. 15.

Multiple grooves 13₁-13₆ are formed on the porous semiconductor layer 12. As shown in FIG. 15, the extraction electrode 34 of the working electrode 100 is disposed on a surface of the transparent electrode 10 extending from an external part of the sealant 16. Similarly, as shown in FIG. 15, the extraction electrode 36 of the counter electrode 18 is disposed on a surface of the counter electrode 18 extending from an external part of the sealant 16.

### Variant Example

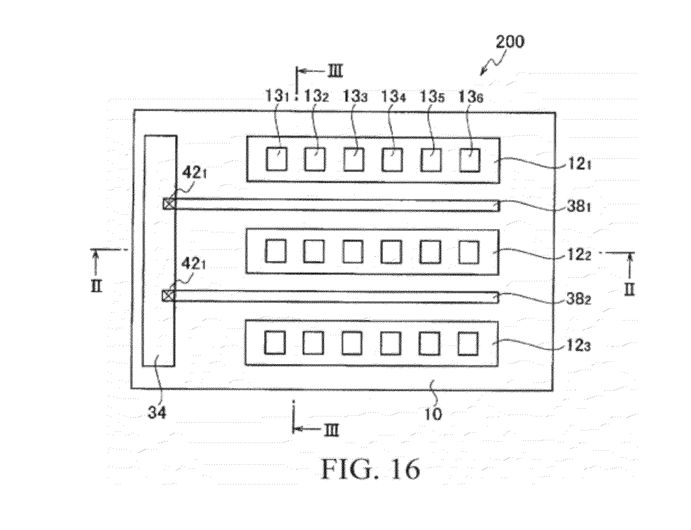

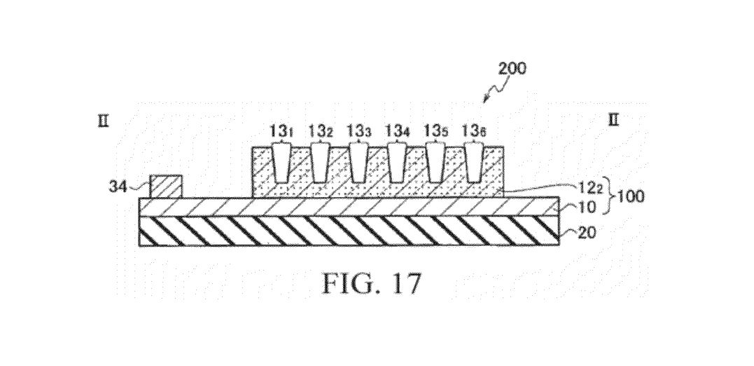

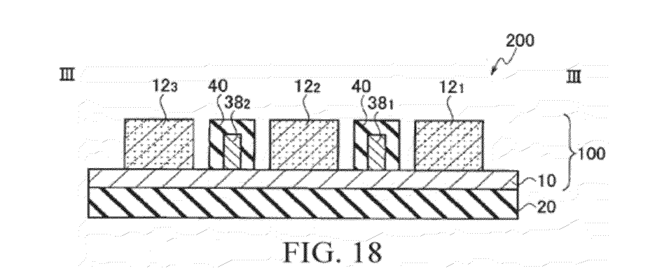

In a DSC 200 according to a variant example of the second embodiment, an extraction electrode 34 of the working electrode 100 is further included, and the a configuration of such set out on a schematic plane pattern is shown in FIG. 16, a schematic cross-sectional structural view long a line II-II in FIG. 16 is shown in FIG. 17, and a schematic cross-sectional structural view along a line III-III in FIG. 16 is shown in FIG. 18. In FIG. 16 to FIG. 18, the configurations of the counter electrode 18, the extraction electrode 36 of the counter electrode 18 and the glass substrate 22 are the same as those of the second embodiment, so the drawings of those are omitted.

In the DSC 200 according to Variant Example of the second embodiment, low-resistance electrodes 38₁-38₂ for conducting electrons generated in porous semiconductor layers 12₁-12₃ are included on the transparent electrode 10 close to the porous semiconductor layers 12₁-12₃.

The difference between the DSC according to Variation Example of the second embodiment and the DSC according to the second embodiment lies in that the low-resistance electrodes 38₁-38₂ connected to the extraction electrode 34 through contacts 42₁-42₂ are included; all other aspects are the same as those of the second embodiment, so details are not repeated herein again. Herein, the low-resistance electrodes 38₁-38₂ may, for example, be formed of Ag, Cu, W and Pt.

In a desirable configuration, the electrons generated in the porous semiconductor layers 12₁-12₃ are directly conducted out to the external circuit.

In the DSC according to Variation Example of the second embodiment, the low-resistance electrodes 38₁-38₂ are connected to the extraction electrode 34 through the contacts 42₁-42₂, so the electrons generated in the porous semiconductor layers 12₁-12₃ are transported to the extraction electrode 34 through the low-resistance electrodes 38₁-38₂.

In the DSC according to Variation Example of the second embodiment, the internal resistance of the porous semiconductor layers 12ᵢ-12₃ can be substantially reduced, so the internal loss is reduced, and the efficiency is improved.

Additionally, because the low-resistance electrodes 38₁-38₂ can be easily corroded by the redox electrolyte contained in the electrolyte solution 14, the low-resistance electrodes 38₁-38₂ may also be coated with a protecting agent 40 formed by, for example, processing a resin with UV.

### (Configuration of a Plane Pattern of the Working Electrode)

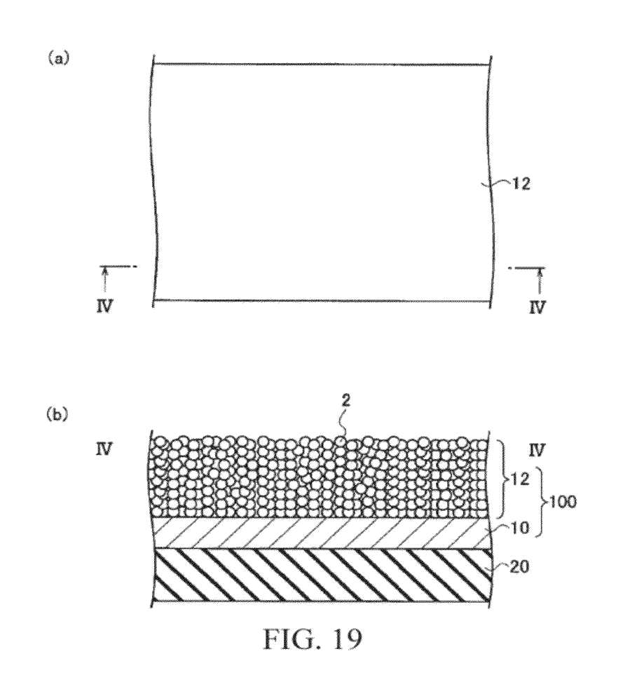

In the DSC according to Comparative Example, a configuration of a plane pattern of the working electrode 100 without being processed through embossing and transfer technology is shown in FIG. 19(a), and a schematic cross-sectional structural view along a line IV-IV in FIG. 19(a) is shown in FIG. 19(b). In Comparative Example, the working electrode 100 is not processed through the embossing and transfer technology, so the porous semiconductor layer 12 having the semiconductor particles 2 containing TiO₂ is formed on the glass substrate 20 with the transparent electrode 10.

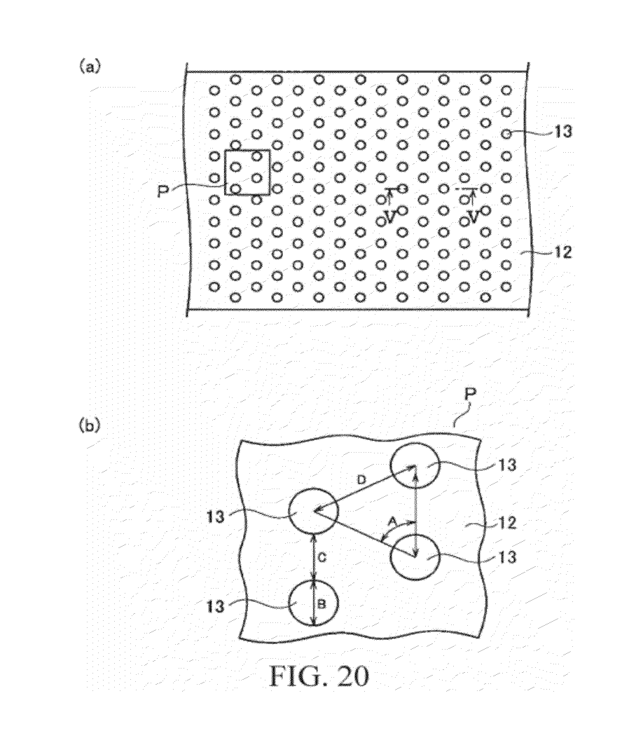

In the DSC according to the second embodiment, a configuration of a schematic plane pattern (Embossed Structure Example 1) of a working electrode 100 formed through the embossing and transfer technology is shown in FIG. 20(a), and an enlarged view of a part P of FIG. 20(a) is shown in FIG. 20(b).

In FIG. 20(b), A represents an angle, B represents a width of the grooves 13, C represents a distance between the grooves 13, and D represents a pitch of the grooves 13. In Embossed Structure Example 1, the grooves 13 are configured to have a triangular plane pattern, and the grooves 13 have a pillar structure.

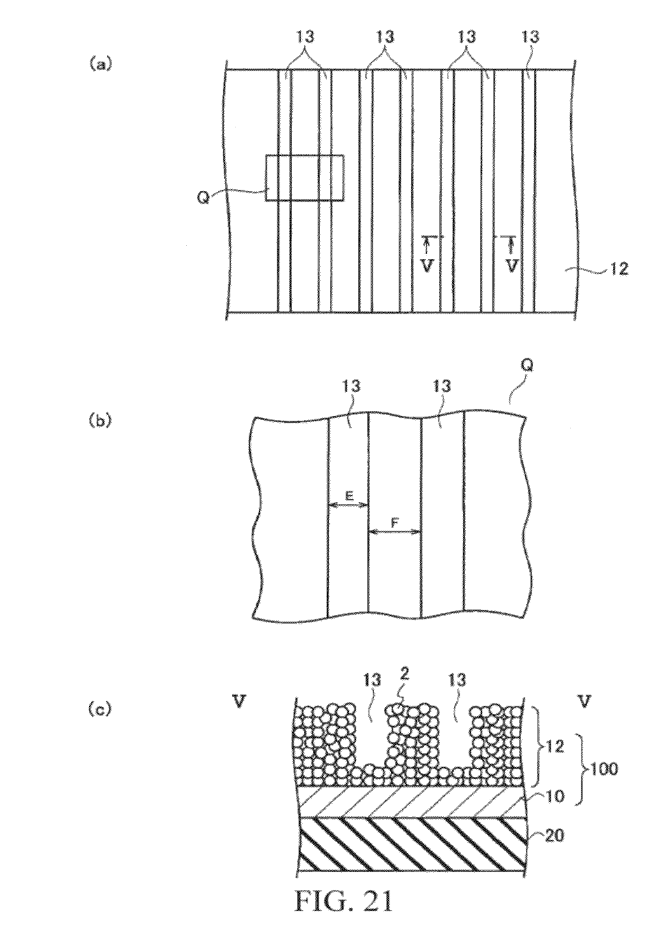

In the DSC according to the second embodiment, a configuration of a schematic plane pattern (Embossed Structure Example 2) of a working electrode formed through the embossing and transfer technology is shown in FIG. 21(a), an enlarged view of a part Q of FIG. 21(a) is shown in FIG. 21(b), and a schematic cross-sectional structural view along a line V-V in FIG. 21(a) is shown in FIG. 21(c). Additionally, a schematic cross-sectional structural view along the line V-V in FIG. 20(a) is also shown in FIG. 21(c).

In FIG. 21(b), E represents a width of the grooves 13, and F represents a distance between the grooves 13. In Embossed Structure Example 2, the grooves 13 are configured to have a strip-like plane pattern, and the protrusion-depression structures of the grooves 13 are linear structures with an interval theretween.

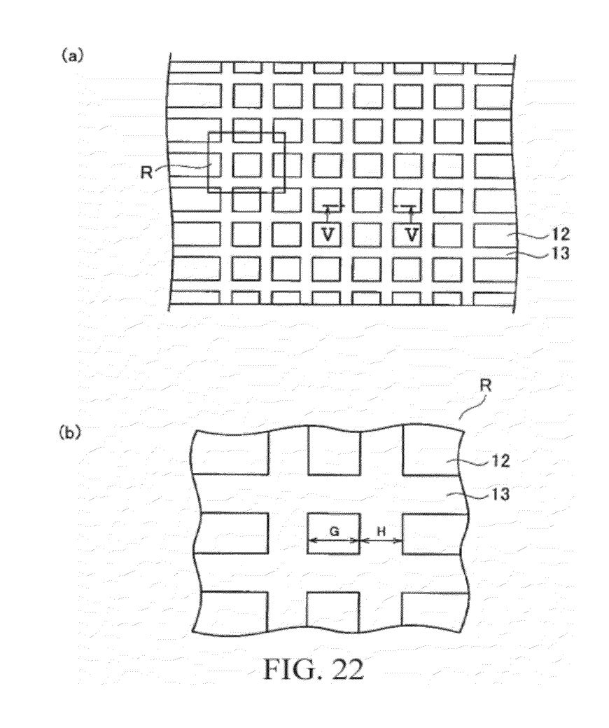

In the DSC according to the second embodiment, a configuration of a schematic plane pattern (Embossed Structure Example 3) of a working electrode formed through the embossing and transfer technology is shown in FIG. 22(a), and an enlarged view of a part Q of FIG. 22(a) is shown in FIG. 22(b). Additionally, a schematic cross-sectional structural view along a line V-V in FIG. 22(a) is also shown in FIG. 21(c).

In FIG. 22(b), H represents a width of the grooves 13, and G represents a distance between the grooves 13. In Embossed Structure Example 3, the grooves 13 are configured to have a network-like plane pattern, and the protrusion-depression structures of the grooves 13 are mesh structures.

In the DSC according to Comparative Example, a distance d1 between a deepest part 12d and a surface S of the porous semiconductor layer 12 is shown in FIG. 23(a). In the DSC according to the second embodiment, a distance d2 between a deepest part 12d and a surface S of a processed porous semiconductor layer 12 is shown in FIG. 23(b).

As shown in FIG. 23(b), the distance d2 between the deepest part 12d and the surface S can be shortened by processing the porous semiconductor layer 12.

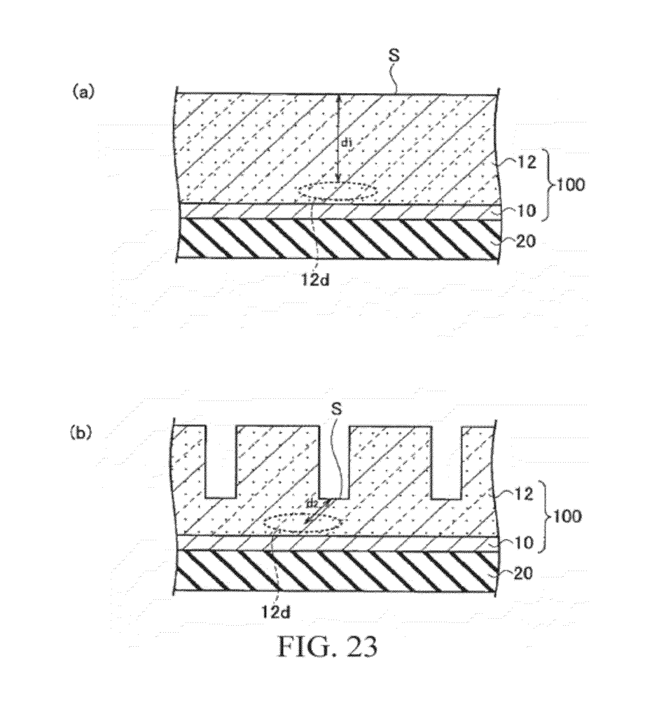

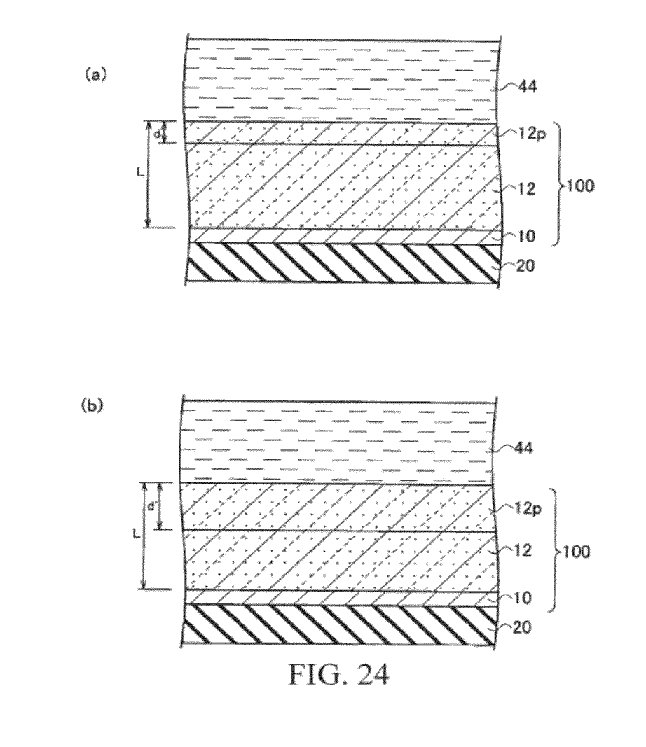

In the DSC according to Comparative Example, a dye penetrated region 12p (an impregnation length d) at an impregnation time t of the porous semiconductor layer 12 is shown in FIG. 24(a), and an impregnation length d′ of the porous semiconductor layer that is greater than d at an impregnation time t′ that is greater than t is shown in FIG. 24(b).

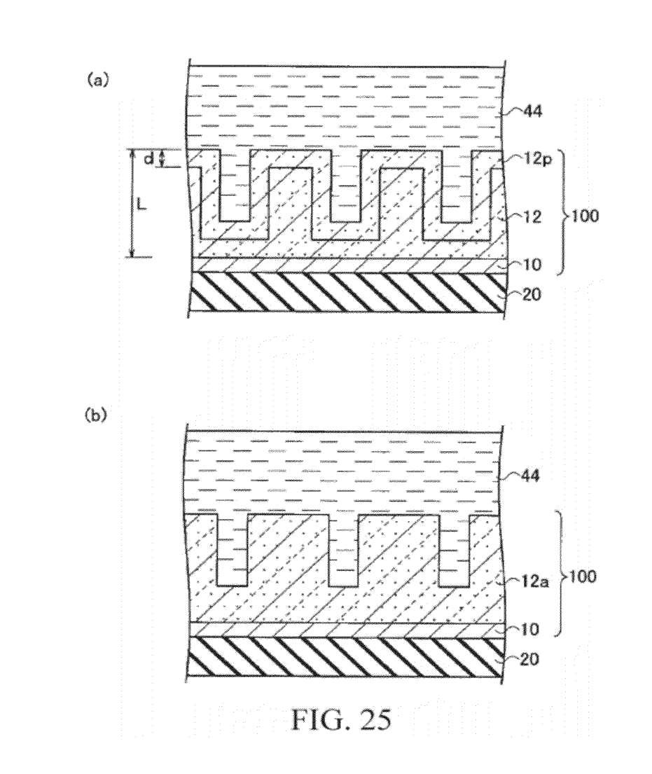

In the DSC according to the second embodiment, a dye penetrated region 12p (an impregnation length d) at an impregnation time t of the porous semiconductor layer 12 is shown in FIG. 25(a), and a porous semiconductor layer 12a at an impregnation time t′ that is greater than t is shown in FIG. 25(b).

As shown in FIG. 25(b), the time taken for the dye to reach the deepest part can be shortened by processing the porous semiconductor layer 12. The porous semiconductor layer 12 becomes the porous semiconductor layer 12a that has fully adsorbed the dye molecules.

### (Experimental Results)

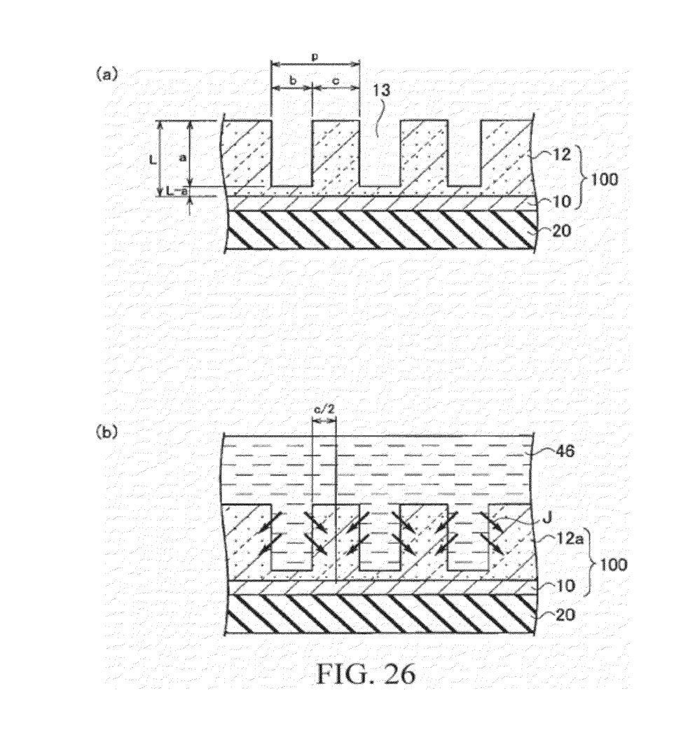

In the DSC according to the second embodiment, a relationship between a cross section of a pattern and sizes of structures is shown in FIG. 26(a), and a necessary impregnation length c/2 accompanying dye adsorption is shown in FIG. 26(b). As shown in FIG. 26, a thickness of the porous semiconductor layer 12 is represented by L, a depth of the grooves 13 is represented by a, a width of the grooves 13 is represented by b, a width of the protrusion is represented by c, and a pitch of the grooves 13 is represented by p. A protrusion occupancy x is represented by c/p. A thickness of a remaining part of the porous semiconductor layer 12 is (L-a).

As shown by an arrow J, the dye fully diffuses from the dye solution 46 in the grooves 13 to the porous semiconductor layer 12, and when the dye molecules have been fully adsorbed across the whole width of the protrusion, the porous semiconductor layer 12 becomes a porous semiconductor layer 12a that has fully adsorbed the dye molecules. c/2 is defined as a necessary impregnation length, and the time needed for the dye molecules to diffuse to the necessary impregnation length c/2 is defined as a necessary impregnation time t.

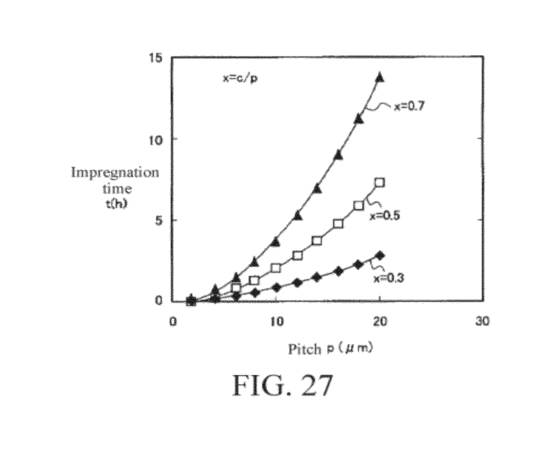

In the DSC according to the second embodiment, a relationship between the necessary impregnation time t required to obtain the necessary impregnation length c/2 and the pitch p with the protrusion occupancy x as a parameter is shown in FIG. 27. The necessary impregnation time t required to obtain the impregnation length c/2 is calculated by using an empirical formula obtained through experiments: t=0.263×d²+0.142 d.

When the protrusion occupancy x is great, the necessary impregnation time t becomes long, and when the protrusion occupancy x is small, the necessary impregnation time t becomes short.

If the pitch p of the grooves 13 is shortened (that is, the width c of the protrusion is shortened), the necessary impregnation time t becomes short.

If the protrusion occupancy x becomes low, and the pitch p of the grooves 13 is short (that is, the width c of the protrusion is short), the processing becomes difficult because the pattern is miniaturized. On the other hand, if the protrusion occupancy x is great, and the pitch p of the grooves 13 is great (that is, the width c of the protrusion is long), the processing becomes easy, but the necessary impregnation time t becomes long.

Therefore, for example, given that the protrusion occupancy x is 0.5 and the pitch p is about 10 μm to 20 μm, the obtained necessary impregnation time t is about 2-8 h, which is beneficial to the processing accuracy and the impregnation time of the dye molecules.

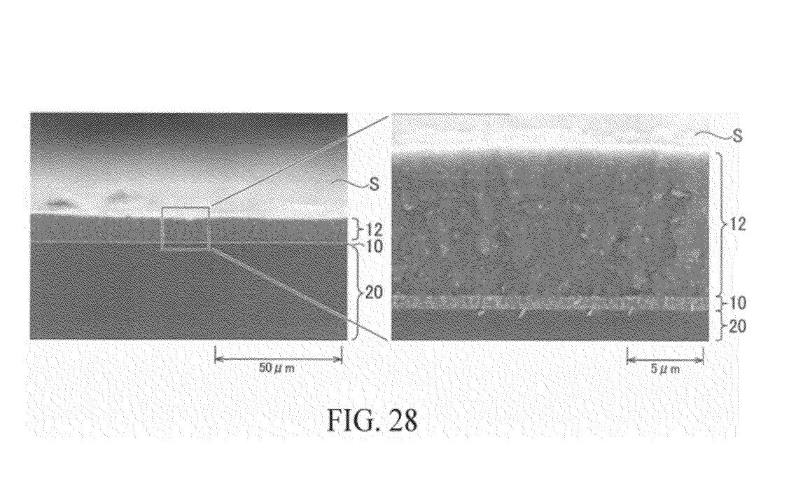

In the DSC according to Comparative Example, an SEM photograph of a cross section close to a surface S of the porous semiconductor layer 12 is shown in FIG. 28. It is known that, the glass substrate 20 has the transparent electrode 10 containing FTO formed thereon, and the transparent electrode 10 has the porous semiconductor layer 12 of about 10 μm formed thereon.

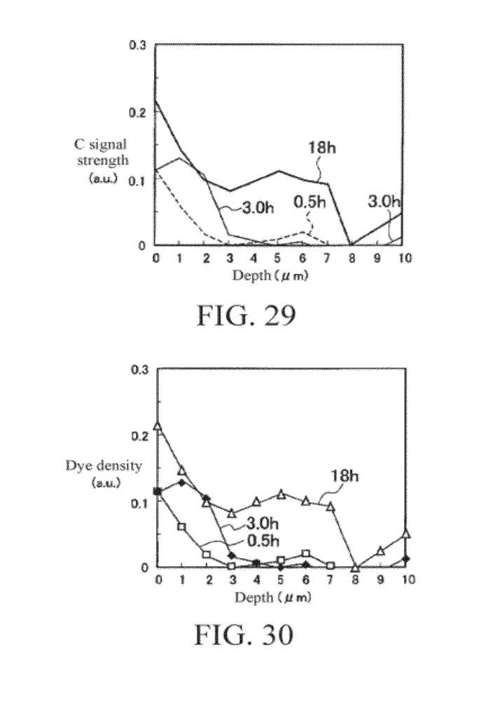

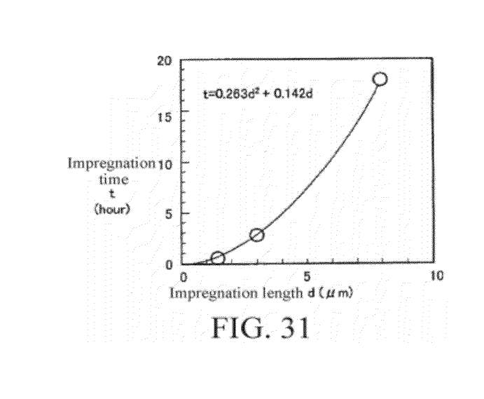

In the DSC according to the second embodiment, a relationship between a C signal strength (in which a signal strength of C atom in the dye molecule represents the concentration of the dye) from an energy dispersive x-ray spectroscope (EDX) and a depth with the impregnation time t as a parameter is shown in FIG. 29, a relationship between a dye density and the depth with the impregnation time t as a parameter is shown in FIG. 30, and a relationship between the impregnation time t and the impregnation length d is shown in FIG. 31.

The impregnation time t required for obtaining the impregnation length d is calculated by the empirical formula of t=0.263×d²+0.142 d.

It is clear from FIG. 29 and FIG. 30 that when the impregnation time t is, for example, about 3.0 h, the impregnation length d is about 3 μm. Therefore, given that the thickness L of the porous semiconductor layer 12 is 10 μm and the width c of the protrusion is about 5 μm, the dye molecules can be fully impregnated into the whole porous semiconductor layer 12 having the protrusion-depression structures. Moreover, given that the width c of the protrusion is about 10 μm, and the impregnation time t is about 8.0 h, the dye molecules can be fully impregnated into the whole porous semiconductor layer 12 having the protrusion-depression structures.

### Embodiment

A TiO₂ slurry was coated onto a glass substrate by a screen printing machine.

After 10-minute baking at 120° C., a TiO₂ slurry film having a thickness of about 10 μm was formed.

A Si substrate with numerous fine protrusions was pressed onto the TiO₂ slurry film by a pressure of about 30 MPa to form fine holes. As for the size of the holes, for example, the depth a is about 6.71 μm, the width b is about 3.36 μm, and the pitch p of the grooves is about 10 μm.

The sample was sintered at a temperature of about 450° C. to form a TiO₂ film useful in the DSC.

In this structure, the distance 1 from the surface of the porous semiconductor layer 12 to the deepest part of the grooves 13 is about 5.35 μm.

In this sample, the time required for adsorbing the dye is about 8 h, and when compared with the time duration of 27 h when the DSC according to the second embodiment is not used, the time is shortened by about 30%.

### (Simulation Results)

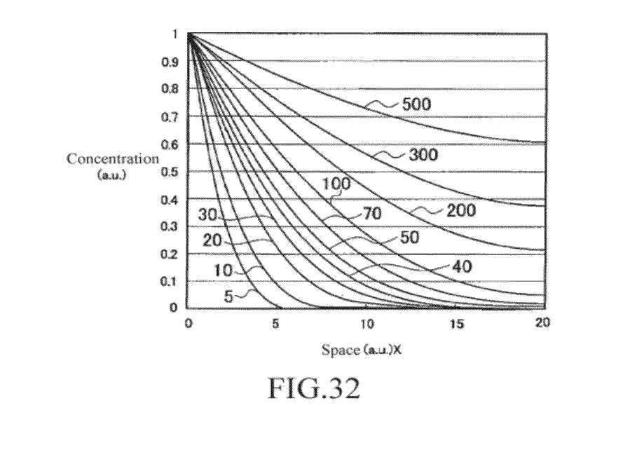

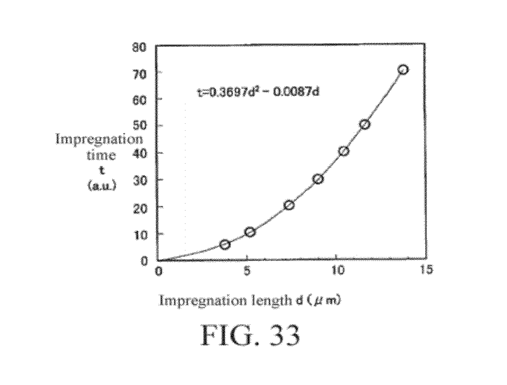

In the DSC according to the second embodiment, a simulation result of a relationship between the concentration of the dye molecules generated due to diffusion in the porous semiconductor layer 12 and a space X with the impregnation time t as a parameter is shown in FIG. 32, and a simulation result of a relationship between the impregnation time t and the impregnation length d is shown in FIG. 33.

FIG. 32 shows a result calculated by using a formula of C_{x,t+Δt}=D·[Δt/(Δx)²]·[C_{x+Δx,t}−2C_{x,t}+C_{x-Δx,t}]+C_{x,t}, which was obtained through differentiating the formula of the second rule of Fick's Law: ∂C/∂t=D·∂²C/∂x². The boundary conditions are when the concentration is fixed to be 1, when x=0, the dye molecules are in contact with the dye solution 46 at the boundary, and when x=20, the dye molecules are in contact with the transparent electrode 10 without diffusion towards the transparent electrode 10.

The results as shown in FIG. 33 are obtained based on FIG. 32, and the impregnation length d is the “impregnation” length when the concentration reaches 0.1.

A relationship formula of the impregnation time t=0.3697×d²−0.0087 d can be obtained from the simulation results of FIG. 32 and FIG. 33, and it is known that the relationship formula represents that t is substantially proportional to d². Therefore, in the adsorption step, an adsorption mode of the dye molecules is substantially a diffusion mode in the TiO₂ film.

### (Die Structure)

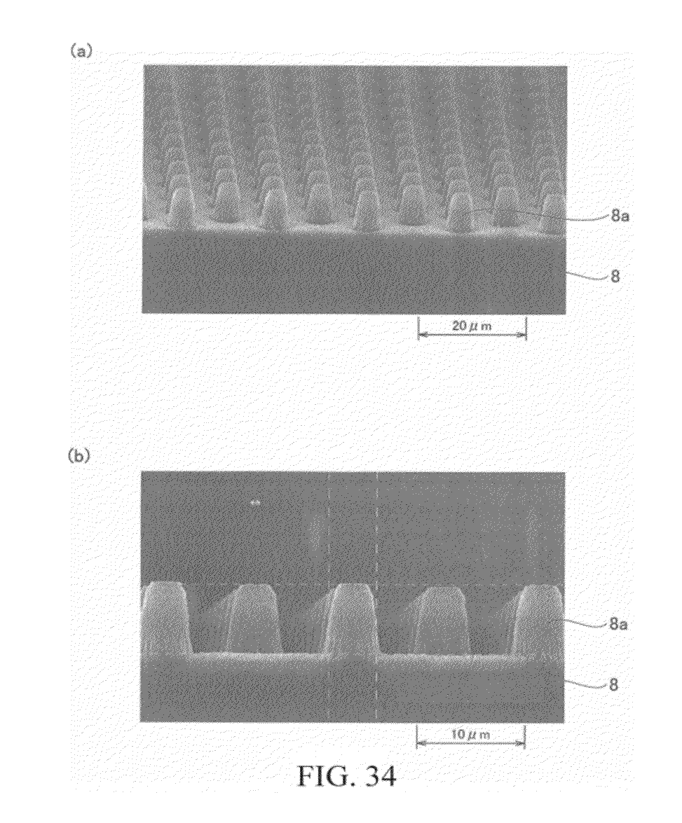

In the DSC according to the second embodiment, an SEM photograph of a surface of a die useful for the embossing and transfer technology is shown in FIG. 34(a), and an SEM photograph of a cross section of the die in the FIG. 34(a) is shown in FIG. 34(b). A pitch of protrusions 8a of a die 8 is about 10 μm.

### (Embossed Porous Semiconductor Layer)

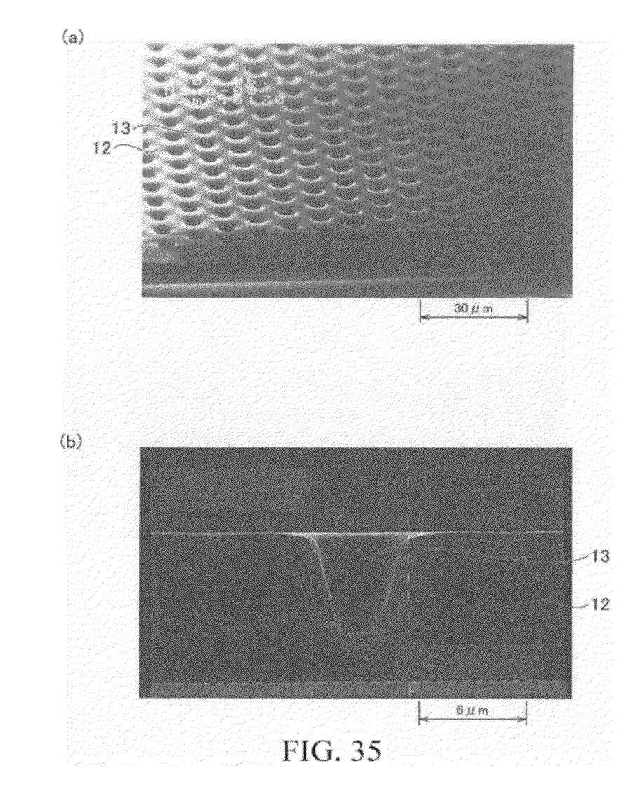

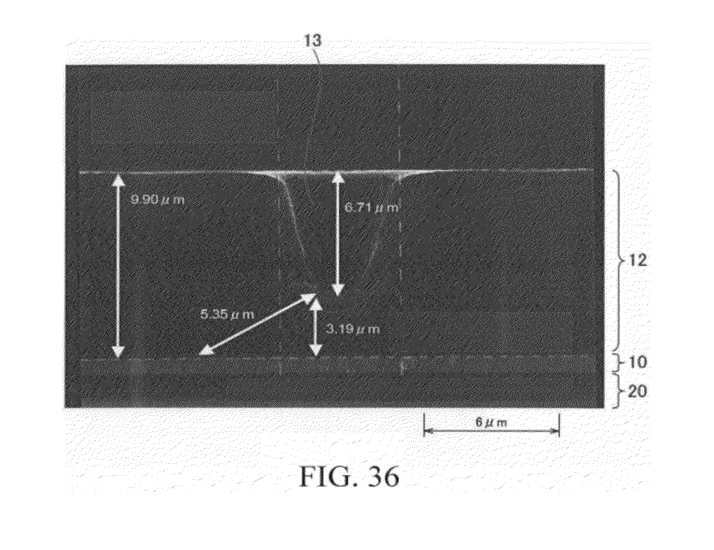

In the DSC according to the second embodiment, an SEM photograph of a surface of the porous semiconductor layer 12 after embossing processing by using the die in FIG. 34 is shown in FIG. 35(a), an enlarged SEM photograph of a cross section of the porous semiconductor layer 12 in FIG. 35(a) is shown in FIG. 35(b), and sizes of parts in the enlarged SEM photograph of the cross section of the porous semiconductor layer 12 in FIG. 35(b) are shown in FIG. 36.

The transfer conditions in the embossing processing include room temperature, a pressure of about 30 MPa, and an embossing time of about 180 s.

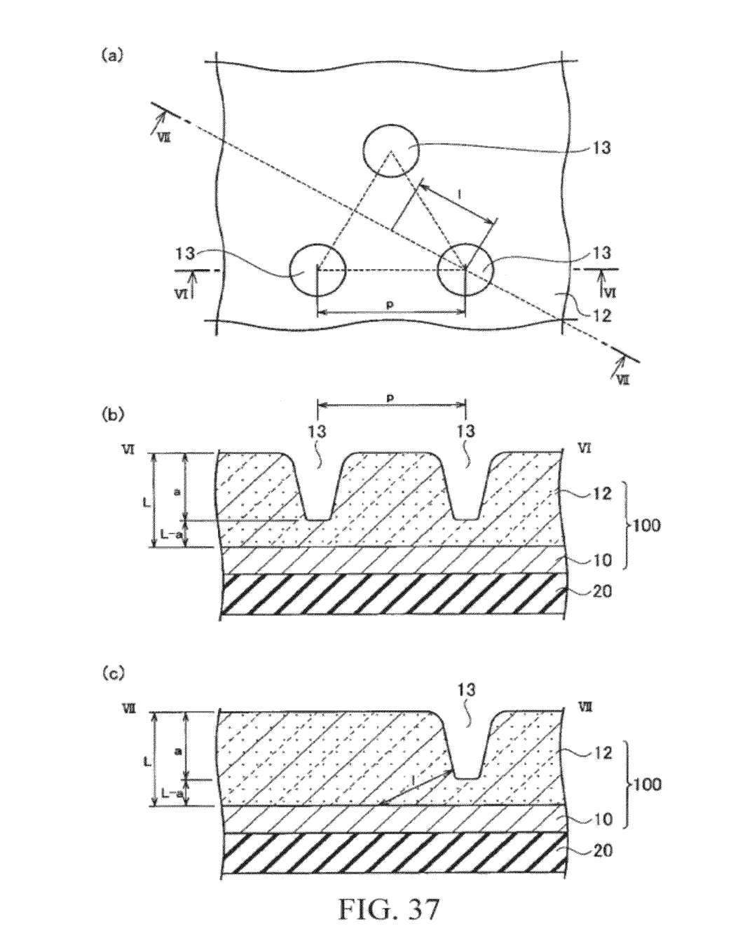

A configuration of a plane pattern in FIG. 35(a) is shown in FIG. 37(a), a schematic cross-sectional structural view of FIG. 37(a) along a line VI-VI is shown in FIG. 37(b), and a schematic cross-sectional structural view of FIG. 37(a) along a line VII-VII is shown in FIG. 37(c).

It is clear from FIG. 36 and FIG. 37(c) that the thickness L of the porous semiconductor layer 12 is about 9.90 μm, the depth a of the grooves 13 is about 6.71 μm, the thickness (L-a) of the remaining part of the porous semiconductor layer 12 is about 3.19 μm, and the distance 1 between the surface of the porous semiconductor layer and the deepest part at the bottom of the grooves 13 configured into an equilateral triangle pattern is about 5.35 μm. Moreover, the width b of the grooves 13 is about 3.36 μm, and the width of the porous semiconductor layer at the bottom of the grooves 13 is about 1.14 μm.

According to the empirical formula of t=0.263×d²+0.142 d, when the impregnation length d is 9.9 μm, the impregnation time t is 27 h, and when the impregnation length d is 5.3 μm, the impregnation time t is 8 h.

In the DSC according to the second embodiment, when compared with the DSC without the protrusion-depression structures, the dye adsorption time can be shorter by about 30% (about 8 h).

(Schematic Structure of Porous Semiconductor Layer Viewed from the Top)

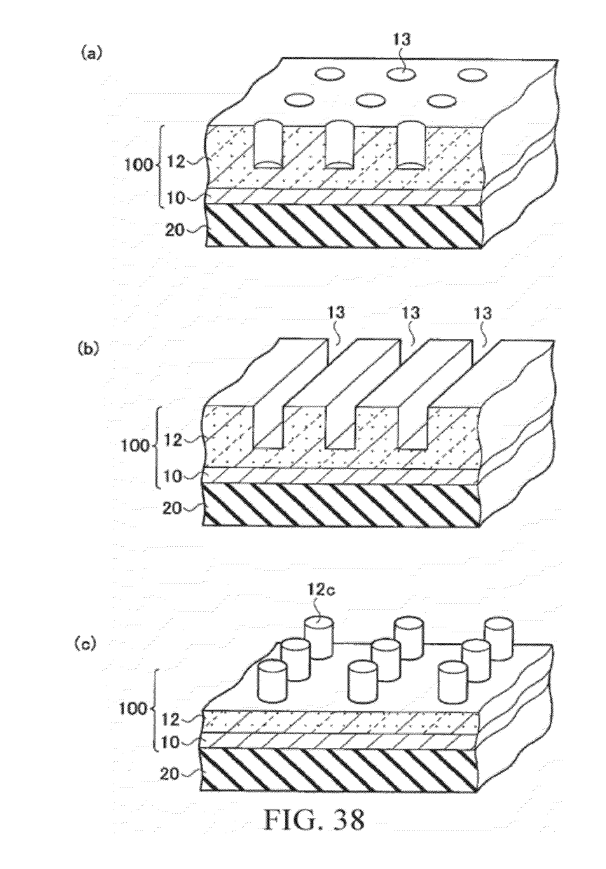

In the DSC according to the second embodiment, Structural Examples 1-3 of the processed porous semiconductor layer are respectively shown in FIGS. 38(a)-(c).

### Structural Example 1

As shown in FIG. 38(a), the grooves 13 of the porous semiconductor layer 12 according to Structural Example 1 are formed by multiple holes (depressions), and the multiple holes (depressions) are, for example, configured into square lattices, triangular lattices or irregular lattices. The shape (the shape viewed from the top) of the holes of the grooves 13 is, for example, a closed curve (for example, a circle and an ellipse) and a polygon (for example, a triangle and a square).

### Structural Example 2

As shown in FIG. 38(b), the porous semiconductor layer 12 according to Structural Example 2 is formed by linear depression-protrusion structures with an interval therebewteen of the grooves 13, in which the depressions are linear. The depression-protrusion structures are configured to be at an equal interval or a varying interval (that is, the width of the line and the interval). The depression-protrusion shape (viewed from the top) is a serpentine shape, a shape with a varying width, a curved shape, a geometrical shape of closed patterns, and a shape formed by combining multiple linear structures with intervals therebetween.

### Structural Example 3

As shown in FIG. 38(c), the porous semiconductor layer 12 according to Structural Example 3 includes multiple protrusions 12c. The multiple protrusions 12c are, for example, configured into square lattices, triangular lattices or irregular lattices. The shape (viewed from the top) of the multiple protrusions 12c is, for example, a closed curve (for example, a circle and an ellipse) and a polygon (for example, a triangle and a square).

### (Structure of Schematic Plane Pattern of the Porous Semiconductor Layer)

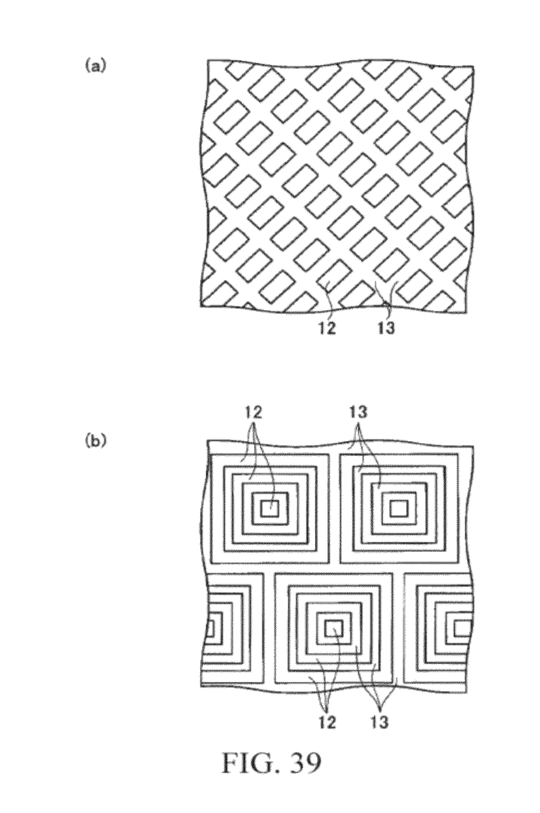

In the DSC according to the second embodiment, Structural Examples 1-2 of a schematic plane pattern of the processed porous semiconductor layer are shown in FIGS. 39(a)-(b).

The depression-protrusion shape (viewed from the top) according to Structural Example 1 in FIG. 39(a) includes a shape of two orthogonal linear structures with intervals.

The depression-protrusion shape (viewed from the top) according to Structural Example 1 in FIG. 39(b) includes a geometrical shape of closed rectangular patterns.

### (Structure of Grooves)

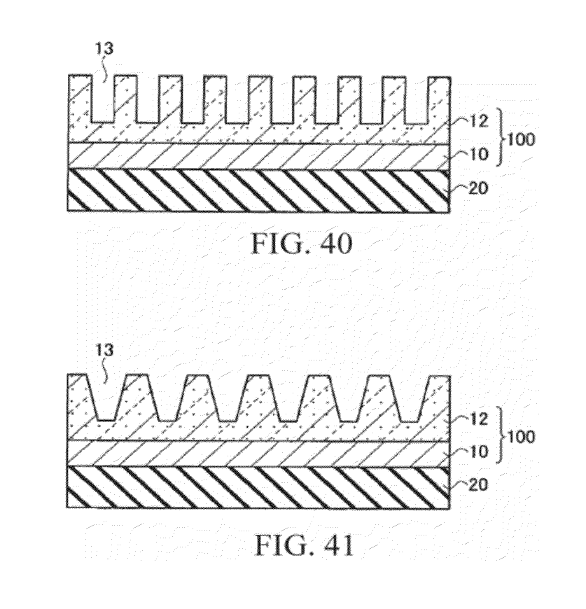

In the DSC according to the second embodiment, a schematic cross-sectional structure of the porous semiconductor layer 12 having grooves 13 with a vertical side wall is shown in FIG. 40.

Referring to FIG. 40 and FIG. 26(a), the grooves 13 have depression-protrusion periodic structures formed in the porous semiconductor layer 12, and if the thickness of the porous semiconductor layer 12 is set to be L, if the depth of the grooves 13 is set to be a, if the width of the grooves 13 is set to be b, and if the width of the protrusion is c, then L is 50 μm or less, and 0<a<L, 0<b<10L and 0<c<10L.

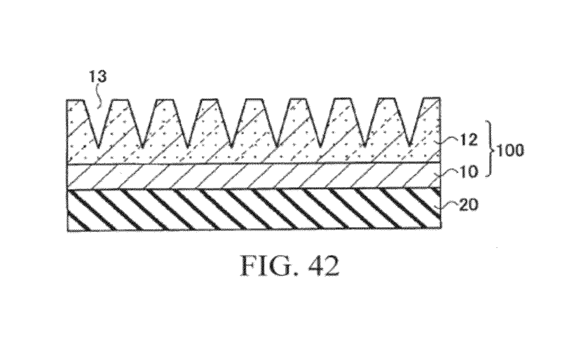

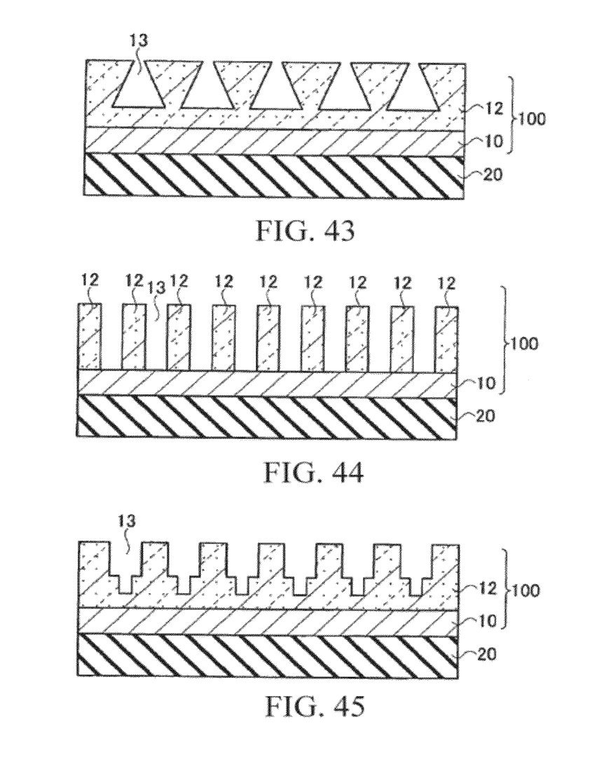

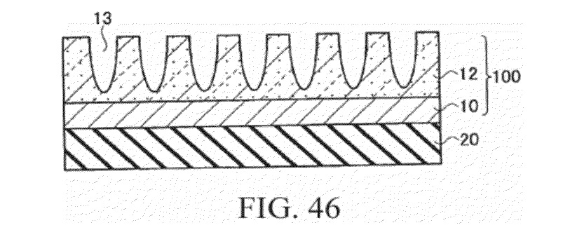

Similarly, a schematic cross-sectional structure of the porous semiconductor layer 12 with the grooves 13 having a taper-shaped side wall is shown in FIG. 41, a schematic cross-sectional structure of the porous semiconductor layer 12 with the wedge-like grooves 13 having a taper-shaped side wall is shown in FIG. 42, a schematic cross-sectional structure of the porous semiconductor layer 12 with the grooves 13 having an inverted taper-shaped side wall is shown in FIG. 43, a schematic cross-sectional structure of the porous semiconductor layer 12 with the grooves 13 reaching the transparent electrode 10 is shown in FIG. 44, a schematic cross-sectional structure of the porous semiconductor layer 12 with the grooves 13 having a side wall of a multi-segment shape is shown in FIG. 45, and a schematic cross-sectional structure of the porous semiconductor layer 12 with the grooves 13 having a side wall of a curved surface is shown in FIG. 46.

In the DSC according to the second embodiment, as shown in FIG. 40 to FIG. 43 and in FIG. 45 and FIG. 46, the side wall of the grooves 13 may have a shape of a vertical shape, a taper shape, a wedge shape, an inverted taper shape, a multi-segment shape, or a curved surface shape.

As shown in FIG. 44, in the DSC according to the second embodiment, the side wall of the grooves 13 may have a vertical shape reaching the first electrode 10.

Moreover, in the DSC according to the second embodiment, the grooves 13 have depression-protrusion periodic structures formed in the porous semiconductor layer 12, and the depression-protrusion structures of the porous semiconductor layer 12 may also include: as shown in FIG. 40(a), a configuration of dot-like depressions in periodic arrangement or in aperiodic dispersion; as shown in FIG. 38(c), a configuration of dot-like protrusions in periodic arrangement or in aperiodic dispersion; as shown in FIG. 38(b), a configuration of protrusions or depressions having periodic or aperiodic repeated linear structures with an interval therebetween; as shown in FIG. 39(a), a configuration of multiple intersecting linear structures with intervals; and as shown in FIG. 39(b), a configuration of a geometrical shape of closed rectangular patterns.

### (Manufacturing Method)

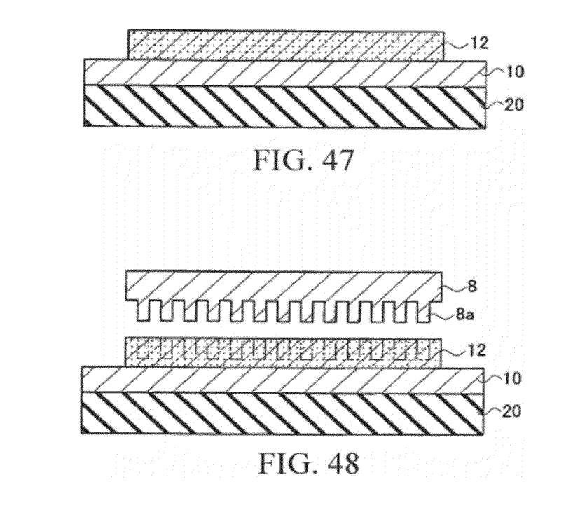

Schematic cross-sectional structural views of the steps of a method for manufacturing the DSC according to the second embodiments are shown in FIG. 47 to FIG. 53.

FIG. 47-FIG. 53 illustrate a method for manufacturing the DSC according to the second embodiment.

(a) First, for example as shown in FIG. 47, after a transparent electrode 10 formed of FTO was formed on a glass substrate 20, a porous semiconductor layer 12 including a TiO₂ slurry film was formed through screen printing. A mixed slurry of particles and an organic solvent was used for forming the semiconductor film. The thickness of the porous semiconductor layer 12 is, for example, about 10 μm Specifically, after being coated, the TiO₂ film slurry was subjected to screen printing, and dried at about 120° C. For example, the steps of coating the TiO₂ slurry film, screen printing and drying were repeated three times. Herein, in addition to screen printing, method such as spin coating, dipping or spraying can also be used.

(b) Next, the porous semiconductor layer 12 was baked at 120° C. for 10 min, and a die 8 having protrusions 8a was embossed on the porous semiconductor layer 12. The embossing conditions include, for example, room temperature, a pressure of about 30 MPa, and a maintenance time of about 180 s. Thereafter, the die 8 was released at room temperature. Herein, the die 8 may, for example, be formed by a Si substrate. In addition to the embossing technology, the method to process the porous semiconductor layer 12 may also be dry etching, wet etching, a forming technology using a sacrificial pattern or a combination thereof.

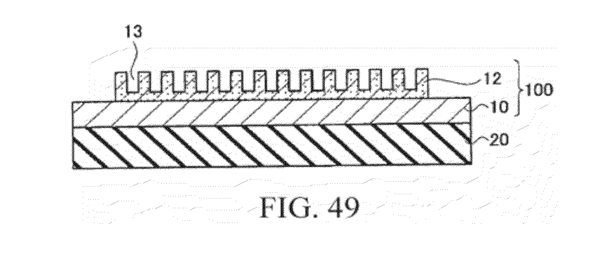

(c) Next, as shown in FIG. 49, the porous semiconductor layer 12 including the TiO₂ slurry film was sintered at a high temperature of about 500° C.

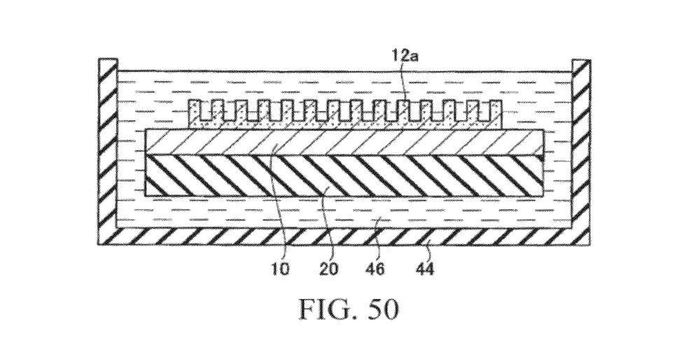

(d) Next, as shown in FIG. 50, the parts including the sintered porous semiconductor layer 12, the transparent electrode 10 and the glass substrate 20 were impregnated in a dye solution container 44 filled with a dye solution 46 for a specific impregnation time t, so that the dye molecules were adsorbed by the porous semiconductor layer 12 with multiple grooves 13.

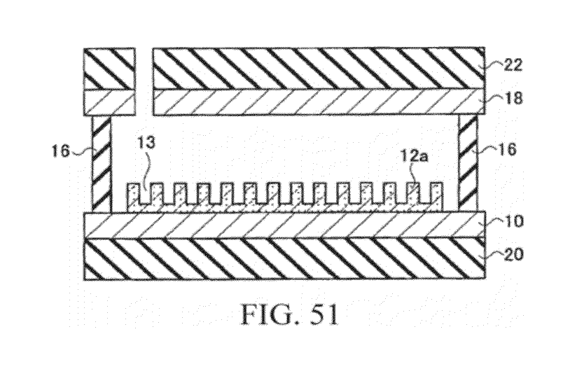

(e) Next, as shown in FIG. 51, the parts of the sintered porous semiconductor layer 12, the transparent electrode 10 and the glass substrate 20 that have fully adsorbed the dye molecules were removed from the dye solution container 44, and a counter electrode 18 was attached through a sealant 16 disposed on the transparent electrode 10. A glass substrate 22 may be adhered to the counter electrode 18 in advance.

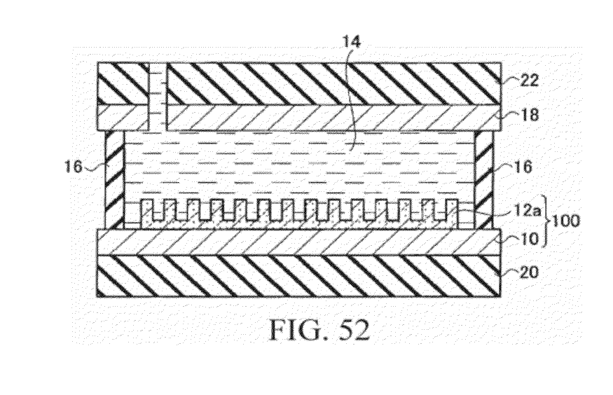

(f) Next, as shown in FIG. 52, an electrolyte solution 14 containing a solvent and an electrolyte formed by mixing multiple redox electrolytes was injected into the space enclosed by the transparent electrode 10, the counter electrode 18, the sealant 16 and the porous semiconductor layer 12a.

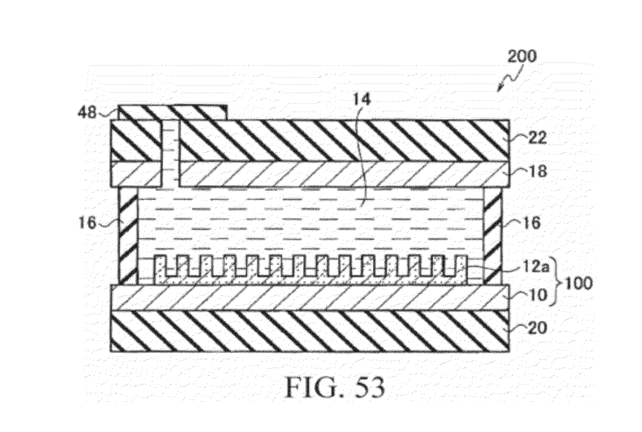

(g) Next, as shown in FIG. 53, a seal plate 48 was disposed on the glass substrate 22, so as to seal the electrolyte solution 14.

### (Manufacturing Method Using Sacrificial Pattern)

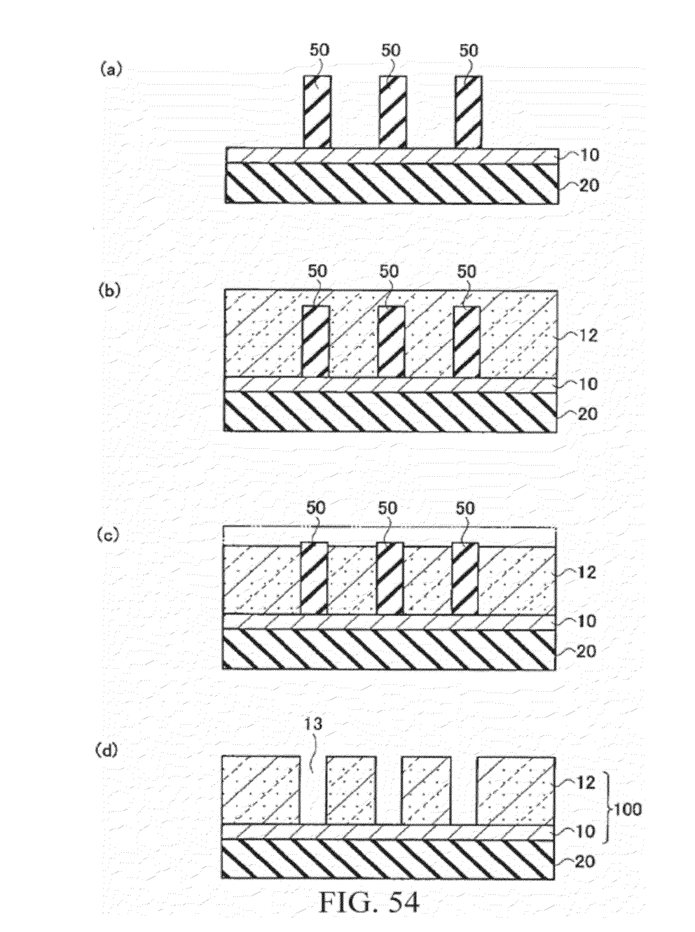

Schematic cross-sectional structural views of the steps of another method for manufacturing the DSC according to the second embodiment are shown in FIGS. 54(a)-(d).

FIGS. 54(a)-(d) illustrate the another method for manufacturing the DSC according to the second embodiment.

(a) First, as shown in FIG. 54(a), after a transparent electrode 10 was formed on a glass substrate 20, SiO₂ were patterned to form a sacrificial layer 50.

(b) Next, as shown in FIG. 54(b), a porous semiconductor layer 12 was formed by coating a semiconductor slurry onto the glass substrate 20 and the sacrificial layer 50. Herein, the step for forming the porous semiconductor layer 12 is the same as that in FIG. 47.

(c) Next, as shown in FIG. 54(c), the porous semiconductor layer 12 was etched back to expose a surface of the sacrificial layer 50.

(d) Next, as shown in FIG. 54 (d), the sacrificial layer 50 was etched by using hydrofluoric acid and then was removed. As a result, a working electrode 100 useful in the DSC 200 according to the second embodiment was formed.

### (Method for Forming Light-Scattering Layer)

Schematic cross-sectional structural views of the steps of another method for manufacturing the DSC according to the second embodiment are shown in FIGS. 55(a)-(b).

FIGS. 55(a)-(b) illustrate the another method for manufacturing the DSC according to the second embodiment.

(a) First, as shown in FIG. 55(a), after a transparent electrode 10 was formed on a glass substrate 20, a pattern of a porous semiconductor layer 12 was formed. That is to say, after a semiconductor slurry film was formed, the porous semiconductor layer 12 was processed through the method of embossing, dry etching, wet etching, using a sacrificial pattern or a combination thereof.

(b) Next, as shown in FIG. 55(b), a light-scattering layer 52 was formed on the pattern of the porous semiconductor layer 12. The light-scattering layer 52 may, for example, be formed of TiO₂ or ZrO₂. The light-scattering layer 52 may, for example, be formed by particles having a particle size of 200 nm. Herein, the light-scattering layer 52 may be formed by coating a slurry of a light scattering material through a method such as screen printing, spin coating, dipping and spraying. As a result, a working electrode 100 was formed, whereby the working electrode 100 was disposed on the porous semiconductor layer 12 and included the light-scattering layer 52 covering grooves 13. The working electrode 100 is useful in the DSC 200 according to the second embodiment.

Schematic cross-sectional structural views of the steps of another method for manufacturing the DSC according to the second embodiment are shown in FIGS. 56(a)-(b).

FIGS. 56(a)-(b) illustrate the another method for manufacturing the DSC according to the second embodiment.

(a) First, as shown in FIG. 56(a), after a transparent electrode 10 was formed on a glass substrate 20, a porous semiconductor layer 12 was formed, and then a light-scattering layer 52 was formed. That is to say, after the semiconductor slurry film was formed, a slurry of a light scattering material was coated through a method that is the same as that for forming the porous semiconductor layer 12, such as screen printing, spin coating, dipping and spraying. The light-scattering layer 52 may, for example, be formed by TiO₂ or ZrO₂. The light-scattering layer 52 may, for example, be formed by particles having a particle size of 200 nm. Herein, the light-scattering layer 52 may be formed by coating a slurry of a light scattering material through a method such as screen printing, spin coating, dipping and spraying.

(b) Next, as shown in FIG. 56(b), the porous semiconductor layer 12 and the light-scattering layer 52 were processed through the embossing technology at the same time. As a result, a working electrode 100 was formed, and the working electrode 100 was disposed on the porous semiconductor layer 12 and included the light-scattering layer 52 covering the grooves 13. The working electrode 100 is useful in the DSC 200 according to the second embodiment.

According to the second embodiment, depression-protrusion structures were formed on the TiO₂ film of the porous semiconductor layer, and the distance between the deepest part and the surface of the TiO₂ film is shortened, so that the insufficiency and excess of the concentration of a specific redox electrolyte with a low diffusion coefficient in the TiO₂ film are prevented, thereby improving the photoelectric conversion efficiency.

According to the second embodiment, by forming the depression-protrusion structures on the TiO₂ film of the porous semiconductor layer, and by shortening the distance between the deepest part and the surface of the TiO₂ film, the time needed for the dye molecules to be impregnated and adsorbed to the deepest part of the TiO₂ film is shortened.

According to the second embodiment, a DSC with an improved photoelectric conversion efficiency and a shortened dye adsorption time can be provided.

According to the second embodiment, a DSC with a generated electricity per unit cost that is greater than that of a currently popular Si solar cell can be provided.

Moreover, according to the second embodiment, by using an electrolyte solution of an electrolyte formed by mixing multiple redox electrolytes in a charge transport layer, a DSC that has a higher open circuit voltage and higher generated electricity can be provided, when compared with the situation that a redox electrolyte is used alone.

Moreover, the DSC according to the embodiments can be used as a power supply for driving various systems.

As described above, the DSC according to the embodiments achieves an elevated voltage by mixing redox electrolytes of an electrolyte solution, thereby improving the dye sensitized performance.

### Third Embodiment

As an electrode structure in the DSC 200 according to the first and the second embodiments, the working electrode 100 is applicable to a laminated energy component.

More specifically, the working electrode 100 in the DSC 200 can be used as internal electrodes of an electric double-layer capacitor (EDLC), internal electrodes of a lithium ion capacitor and internal electrodes of a lithium ion cell.

### (EDLC)

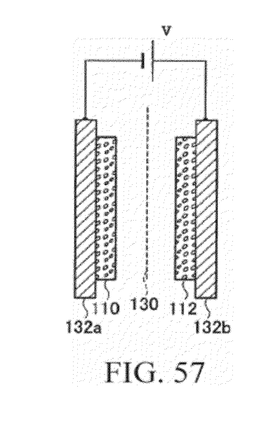

FIG. 57 shows a basic structure of internal electrodes of an electric double-layer capacitor (EDLC) according to a third embodiment. The internal electrodes of the EDLC have such a configuration that a separator 130 that merely allows ions of an electrolyte solution to pass through is inserted into at least one layer of active material electrodes 110 and 112, drain electrodes 132a and 132b are exposed to the active material electrodes 110 and 112, and the drain electrodes 132a and 132b are connected to a source voltage. The drain electrodes 132a and 132b are, for example, formed by an aluminum foil, and the active material electrodes 110 and 112 are, for example, formed by active carbon. The separator 130 has an area that is greater than those of the active material electrodes 110 and 112, so as to cover the whole active material electrodes 110 and 112. In principle, the separator 130 does not depend on the type of the energy component; however, in a situation where reflow processing is necessary, the separator 130 is required to be heat resistant. In case where heat resistance is not required, polypropylene can be used, and in case where heat resistance is required, celluloses can be used. The external electrodes of the EDLC are impregnated with the electrolyte solution, and merely allow the ions of the electrolyte solution to move through the separator 130 to become charged or discharged.

### (Lithium Ion Capacitor)

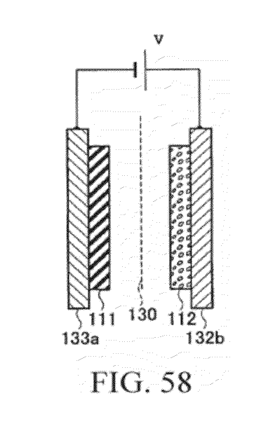

FIG. 58 shows a basic structure of internal electrodes of a lithium ion capacitor according to the third embodiment. External electrodes of the lithium ion capacitor have such a configuration that a separator 130 that merely allows ions of an electrolyte solution to pass through is inserted into at least one layer of active material electrodes 111 and 112, drain electrodes 133a and 132b are exposed to the active material electrodes 110 and 112, and the drain electrodes 133a and 132b are connected to a source voltage. The active material electrode 112 at a positive electrode side is, for example, formed by active carbon, and the active material electrode 111 at a negative electrode side is, for example, formed by Li doped carbon. The drain electrode 132b at the positive electrode side is, for example, formed by an aluminum foil, and the drain electrode 133a at the negative electrode side is, for example, formed by a copper foil. The separator 130 has an area that is greater than those of the active material electrodes 111 and 112, so as to cover the whole active material electrodes 111 and 112. The internal electrodes of the lithium ion capacitor are impregnated with the electrolyte solution, and merely allow the ions of the electrolyte solution to move through the separator 130 to become charged or discharged.

### (Lithium Ion Cell)

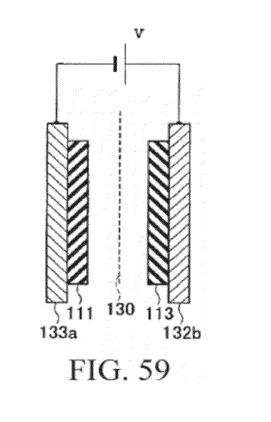

FIG. 59 shows a basic structure of internal electrode of a lithium ion cell according to the third embodiment. External electrodes of the lithium ion cell have such a configuration that a separator 130 that merely allows ions of an electrolyte solution to pass through is inserted into at least one layer of active material electrodes 111 and 113, drain electrodes 133a and 132b are exposed to the active material electrodes 111 and 113, and the drain electrodes 133a and 132b are connected to a source voltage. The active material electrode 113 at a positive electrode side is, for example, formed by LiCOO₂, and the active material electrode 111 at a negative electrode side is, for example, formed by Li doped carbon. The drain electrode 132b at the positive electrode side is, for example, formed by an aluminum foil, and the drain electrode 133a at the negative electrode side is, for example, formed by a copper foil. The separator 130 has an area that is greater than those of the active material electrodes 111 and 113, so as to cover the whole active material electrodes 111 and 113. The internal electrodes of the lithium ion cell are impregnated with the electrolyte solution, and merely allow the ions of the electrolyte solution to move through the separator 130 to become charged or discharged.

### Other Embodiments

As described above, the present invention is described with reference to the first and the second embodiments and Variant Example thereof, and the third embodiment, but the description and the accompanying drawings that form a part of the disclosed content are intended to be exemplary only, and should not be construed as limitations to the present invention. Persons of skill in the art can obtain various alternative embodiments, embodiments and application technologies according to the disclosed content.

In this way, the present invention includes various embodiments that are not described herein.

The DSC of the present invention is applicable to various systems as a power supply.

While embodiments of the present invention have been illustrated and described, various modifications and improvements can be made by persons skilled in the art. It is intended that the present invention is not limited to the particular forms as illustrated, and that all the modifications not departing from the spirit and scope of the present invention are within the scope as defined in the following claims.

What is claimed is:

1. A dye-sensitized solar cell (DSC), comprising:
a first substrate;
a first electrode, disposed on the first substrate;
a porous semiconductor layer, disposed on the first electrode; and
a charge transport layer, in contact with the porous semiconductor layer, and having a solvent and multiple redox electrolytes.

2. The DSC according to claim 1, wherein the redox electrolyte comprises a mixture system selected from the group consisting of an iodine-based redox electrolyte, a bromine-based redox electrolyte, a chlorine-based redox electrolyte and ferrocene.

3. The DSC according to claim 1, wherein the porous semiconductor layer has grooves on a surface that is not in contact with the first electrode.

4. The DSC according to claim 3, further comprising on the first electrode, a low-resistance electrode, close to the porous semiconductor layer, for conducting electrons generated in the porous semiconductor layer.

5. The DSC according to claim 3, further comprising a light-scattering layer, disposed on the porous semiconductor layer, and covering the grooves.

6. The DSC according to claim 3, wherein a side wall of the grooves has a shape of a vertical shape, a taper shape, a wedge shape, an inverted taper shape, a multi-segment shape, or a curved surface shape.

7. The DSC according to claim 3, wherein a side wall of the grooves has a vertical shape and reaches the first electrode.

8. The DSC according to claim 3, wherein the grooves has depression-protrusion periodic structures formed in the porous semiconductor layer, and the depression-protrusion structures of the porous semiconductor layer comprise: a configuration of dot-like depressions in periodic arrangement or in aperiodic dispersion; a configuration of dot-like protrusions in periodic arrangement or in aperiodic dispersion; a configuration of protrusions or depressions having periodic or aperiodic repeated linear structures with an interval therebetween; a configuration of multiple intersecting linear structures with intervals; or a configuration of a geometric shape of closed rectangular patterns.

9. The DSC according to claim 3, wherein the grooves has a depression-protrusion periodic structure formed in the porous semiconductor layer, and the thickness of the porous semiconductor layer is set to be L, the depth of the grooves is set to be a, and the width of the grooves is set to be b, and the width of the protrusion is set to be c, then L=50 μm or less, 0<a<L, 0<b<10L and 0<c<10L.

10. A dye-sensitized solar cell (DSC), comprising:
a first substrate;
a first electrode, disposed on the first substrate;
a porous semiconductor layer, disposed on the first electrode, and comprising semiconductor particles and dye molecules;
an electrolyte solution, formed by dissolving a redox electrolyte in a solvent, in contact with the porous semiconductor layer;
a second electrode, in contact with the electrolyte solution;
a second substrate, disposed on the second electrode; and
a sealant, disposed between the first substrate and the second substrate, for sealing the electrolyte solution,
wherein the redox electrolyte comprises an electrolyte formed by mixing multiple redox electrolytes.

11. The DSC according to claim 10, wherein the redox electrolyte comprises a mixture system selected from the group consisting of an iodine-based redox electrolyte, a bromine-based redox electrolyte, a chlorine-based redox electrolyte and ferrocene.

12. The DSC according to claim 10, wherein the electrolyte solution comprises primary to quaternary ammonium ions, bromine ions and iodide ions.

13. The DSC according to claim 12, wherein the concentration of the bromine ion in the electrolyte solution is lower than the concentration of the iodide ion.

14. The DSC according to claim 13, wherein the concentration of the bromine ion in the electrolyte solution is one half or less of the concentration of the iodide ion.

15. The DSC according to claim 12 wherein the primary to quaternary ammonium ions comprise any one of tetrabutyl ammonium, tetramethyl ammonium, trimethylmethanaminium, hexadecyl-trimethyl-ammonium, trimethylanilinium or trimethylbenzeneaminium.

16. The DSC according to claim 13 wherein the primary to quaternary ammonium ions comprise any one of tetrabutyl ammonium, tetramethyl ammonium, trimethylmethanaminium, hexadecyl-trimethyl-ammonium, trimethylanilinium or trimethylbenzeneaminium.

17. The DSC according to claim 14 wherein the primary to quaternary ammonium ions comprise any one of tetrabutyl ammonium, tetramethyl ammonium, trimethylmethanaminium, hexadecyl-trimethyl-ammonium, trimethylanilinium or trimethylbenzeneaminium.

18. The DSC according to claim 10, wherein the porous semiconductor layer has grooves on a surface that is not in contact with the first electrode.

19. The DSC according to claim 18, further comprising on the first electrode, a low-resistance electrode, close to the porous semiconductor layer, for conducting electrons generated in the porous semiconductor layer.

20. The DSC according to claim 18, further comprising a light-scattering layer, disposed on the porous semiconductor layer, and covering the grooves.

21. The DSC according to claim 18, wherein a side wall of the grooves has a shape of a vertical shape, a taper shape, a wedge shape, an inverted taper shape, a multi-segment shape, or a curved surface shape.

22. The DSC according to claim 18, wherein a side wall of the grooves has a vertical shape and reaches the first electrode.

23. The DSC according to claim 18, wherein the grooves has depression-protrusion periodic structures formed in the porous semiconductor layer, and the depression-protrusion structures of the porous semiconductor layer comprise: a configuration of dot-like depressions in periodic arrangement or in aperiodic dispersion; a configuration of dot-like protrusions in periodic arrangement or in aperiodic dispersion; a configuration of protrusions or depressions having periodic or aperiodic repeated linear structures with an interval therebetween; a configuration of multiple intersecting linear structures with intervals; or a configuration of a geometric shape of closed rectangular patterns.

24. The DSC according to claim 18, wherein the grooves has a depression-protrusion periodic structure formed in the porous semiconductor layer, and the thickness of the porous semiconductor layer is set to be L, the depth of the grooves is set to be a, and the width of the grooves is set to be b, and the width of the protrusion is set to be c, then L=50 μm or less, 0<a<L, 0<b<10L and 0<c<10L.

25. An electric double-layer capacitor (EDLC), wherein internal electrodes of the EDLC have an electrode structure of the dye-sensitized solar cell (DSC) according to claim 1.

26. An electric double-layer capacitor (EDLC), wherein internal electrodes of the EDLC have an electrode structure of the dye-sensitized solar cell (DSC) according to claim 10.

27. A lithium ion capacitor, wherein internal electrodes of the lithium ion capacitor have an electrode structure of the dye-sensitized solar cell (DSC) according to claim 1.

28. A lithium ion capacitor, wherein internal electrodes of the lithium ion capacitor have an electrode structure of the dye-sensitized solar cell (DSC) according to claim 10.

29. A lithium ion cell, wherein internal electrodes of the lithium ion cell have an electrode structure of the dye-sensitized solar cell (DSC) according to claim 1.

30. A lithium ion cell, wherein internal electrodes of the lithium ion cell have an electrode structure of the dye-sensitized solar cell (DSC) according to claim 10.
